(19) United States
(12) Patent Application Publication
(10) Pub. No.: US 2018/0151709 A1
(43) Pub. Date: May 31, 2018

(54) SEMICONDUCTOR DEVICE, SUBSTRATE AND ELECTRICAL POWER CONVERSION DEVICE

(71) Applicant: HITACHI, LTD., Chiyoda-ku, Tokyo (JP)

(72) Inventors: Hiroyuki YOSHIMOTO, Tokyo (JP); Naoki WATANABE, Tokyo (JP)

(21) Appl. No.: 15/577,501

(22) PCT Filed: Jun. 1, 2015
(86) PCT No.: PCT/JP2015/065808

§ 371 Date: Nov. 28, 2017

(51) Int. Cl. H01L 29/739; H01L 29/08; H01L 29/10; H01L 29/423; H01L 29/417; H01L 29/36; H01L 29/16; H01L 29/66

(52) U.S. Cl. CPC H01L 29/7395; H01L 29/0821; H01L 29/1095; H01L 29/0804; H01L 29/4236; H01L 29/41708; H01L 29/45; H01L 29/1608; H01L 29/7397; H01L 29/66068; H01L 29/66333; H01L 29/66348; H01L 29/36

(57) ABSTRACT

An n-type drift layer DRL formed on a buffer layer BUF in a semiconductor device (SiC-IGBT) is configured so as to have (c1) an n-type first drift region DRL1 formed on the buffer layer BUF and (c2) an n-type second drift region DRL2 formed on the first drift region DRL1, (c3) an impurity concentration of the first drift region DRL1 is made lower than an impurity concentration of the buffer layer BUF and higher than an impurity concentration of the second drift region DRL2, and (c4) the first drift region DRL1 is made thinner than the second drift region DRL2. By forming the drift layer DRL so as to have a stacked structure as described above, an electric field on a surface on an emitter region side can be lowered at the OFF time of the semiconductor device even if a high voltage is applied. Moreover, at the time of switching, noises can be reduced since a carrier-stored region can be ensured.

### TECHNICAL FIELD

The present invention relates to a semiconductor device, a substrate and an electrical power conversion device, and also relates a technique effectively applicable to, for example, a semiconductor device including a power semiconductor element, a substrate for use in the power semiconductor element and an electrical power conversion device having the power semiconductor element.

### BACKGROUND ART

For electrical power conversion devices ranging from small electrical power appliances such as home electric appliances to large electrical power appliances such as electric automobiles, railways, electrical power distribution systems and others, an IGBT that is one type of power semiconductor elements has been widely used as a switching element.

For example, the following Patent Document 1 has disclosed an IGBT having a drift region composed of a first low concentration region, a high concentration region and a second low concentration region.

Moreover, the following Non-Patent Document 1 has disclosed an IGBT element using SiC, the IGBT element having a breakdown voltage exceeding 15 kV.

### RELATED ART DOCUMENTS

### Patent Document

Patent Document 1: Japanese Patent Application Laid-open Publication No. 2008-258262

### Non-Patent Document

Non-Patent Document 1: Woongje Sung, Jun Wang, Alex Q. Huang, B. Jayant Baliga, ISPSD 2009. 21^{st}. International Symposium on, pp. 271 to 274 (2009)

### SUMMARY OF THE INVENTION

### Problems to be Solved by the Invention

The SiC which is a compound semiconductor material has a band gap of about 3 times as large as and a dielectric-breakdown electric field intensity of about 10 times as large as those of Si which is a semiconductor material widely used for electronic devices.

For this reason, it is expected to use the IGBT element using SiC under such a very large breakdown voltage as to exceed, for example, 6.5 kV. However, although described in detail later, there are problems of noise generation at the time of switching and a high electric field on an emitter region side at the time of a high voltage application, and these problems have a trade-off relation.

Therefore, it is desirable to achieve both of suppression of the noise generation at the time of switching and reduction of the electric field on the emitter region side at the time of the high voltage application.

Other object and novel characteristics will be apparent from the description of the present specification and the accompanying drawings.

### Means for Solving the Problems

The summary of the typical aspects of the inventions disclosed in the present application will be briefly described as follows.

A semiconductor device shown in one embodiment disclosed in the present application includes an insulated gate bipolar transistor. This insulated gate bipolar transistor has a drift layer. This drift layer has (c1) a second conductivity-type first drift region formed on a buffer layer and (c2) a second conductivity-type second drift region formed on the first drift region. Moreover, (c3) the impurity concentration of the first drift region is lower than the impurity concentration of the buffer layer and higher than the impurity concentration of the second drift region, and (c4) the first drift region is thinner than the second drift region.

The substrate shown in one embodiment disclosed in the present application is a substrate having a substrate layer. This substrate layer has (a) a first conductivity-type collector region including a first surface and a second surface on the side opposite to the first surface, (b) a second conductivity-type buffer layer formed on the first surface in the collector region and (c) a second conductivity-type drift layer formed on the buffer layer. Further, the drift layer has (c1) a second conductivity-type first drift region formed on the buffer layer and (c2) a second conductivity-type second drift region formed on the first drift region. Moreover, (c3) the impurity concentration of the first drift region is lower than the impurity concentration of the buffer layer and higher than the impurity concentration of the second drift region, and (c4) the first drift region is thinner than the second drift region. Furthermore, the collector region, the buffer layer, the first drift region and the second drift region are epitaxial layers.

### Effects of the Invention

According to a semiconductor device shown in a typical embodiment disclosed below in the present application, characteristics of the semiconductor device can be improved.

According to a substrate shown below in the typical embodiment disclosed in the present application, a semiconductor device having favorable characteristics can be manufactured by using this substrate.

### BRIEF DESCRIPTIONS OF THE DRAWINGS

FIG. 1 is a cross-sectional view showing a configuration of a semiconductor device according to a first embodiment;

FIG. 2 is a graph showing static characteristics obtained when each of an Si-IGBT, an SiC-MOSFET and an SiC-IGBT is conducted;

FIG. 3 is a cross-sectional view showing a configuration of a semiconductor device according to a comparative example of the first embodiment;

FIG. 4 is a conceptual diagram showing an internal electric field of a drift layer in a case of setting the drift layer at a high concentration in the semiconductor device of the comparative example;

FIG. 5 is a conceptual diagram showing waveforms of a collector current and a collector voltage in the case of setting the drift layer at a high concentration in the semiconductor device of the comparative example;

FIG. 6 is a conceptual diagram showing the internal electric field of the drift layer in a case of setting the drift layer at a low concentration in the semiconductor device of the comparative example;

FIG. 7 is a conceptual diagram showing waveforms of a collector current and a collector voltage in the case of setting the drift layer at the low concentration in the semiconductor device of the comparative example;

FIG. 8 is a conceptual diagram showing a relation between a configuration of the drift layer and an internal electric field of the drift layer;

FIG. 9 is a conceptual diagram showing a relation between the configuration of the drift layer and the internal electric field of the drift layer;

FIG. 10 is a cross-sectional view showing manufacturing processes of a semiconductor device of the first embodiment;

FIG. 11 is a cross-sectional view showing the manufacturing processes of the semiconductor device of the first embodiment, which is the cross-sectional view showing the manufacturing processes of the semiconductor device continued from FIG. 10;

FIG. 12 is a cross-sectional view showing the manufacturing processes of the semiconductor device of the first embodiment, which is the cross-sectional view showing the manufacturing processes of the semiconductor device continued from FIG. 11;

FIG. 13 is a cross-sectional view showing the manufacturing processes of the semiconductor device of the first embodiment, which is the cross-sectional view showing the manufacturing processes of the semiconductor device continued from FIG. 12;

FIG. 14 is a cross-sectional view showing the manufacturing processes of the semiconductor device of the first embodiment, which is the cross-sectional view showing the manufacturing processes of the semiconductor device continued from FIG. 13;

FIG. 15 is a cross-sectional view showing the manufacturing processes of the semiconductor device of the first embodiment, which is the cross-sectional view showing the manufacturing processes of the semiconductor device continued from FIG. 14;

FIG. 16 is a cross-sectional view showing the manufacturing processes of the semiconductor device of the first embodiment, which is the cross-sectional view showing the manufacturing processes of the semiconductor device continued from FIG. 15;

FIG. 17 is a cross-sectional view showing the manufacturing processes of the semiconductor device of the first embodiment, which is the cross-sectional view showing the manufacturing processes of the semiconductor device continued from FIG. 16;

FIG. 18 is a cross-sectional view showing manufacturing processes of a semiconductor device according to an applied example of the first embodiment;

FIG. 19 is a cross-sectional view showing manufacturing processes of the semiconductor device according to the applied example of the first embodiment, which is the cross-sectional view showing the manufacturing processes of the semiconductor device continued from FIG. 18;

FIG. 20 is a cross-sectional view showing the manufacturing processes of the semiconductor device of the applied example of the first embodiment, which is the cross-sectional view showing the manufacturing processes of the semiconductor device continued from FIG. 19;

FIG. 21 is a cross-sectional view showing a configuration of a semiconductor device according to a second embodiment;

FIG. 22 is a cross-sectional view showing manufacturing processes of a semiconductor device according to the second embodiment;

FIG. 23 is a cross-sectional view showing manufacturing processes of the semiconductor device according to the second embodiment, which is the cross-sectional view showing the manufacturing processes of the semiconductor device continued from FIG. 22;

FIG. 24 is a cross-sectional view showing manufacturing processes of the semiconductor device according to the second embodiment, which is the cross-sectional view showing the manufacturing processes of the semiconductor device continued from FIG. 23;

FIG. 25 is a cross-sectional view showing manufacturing processes of the semiconductor device according to the second embodiment, which is the cross-sectional view showing the manufacturing processes of the semiconductor device continued from FIG. 24;

FIG. 26 is a cross-sectional view showing manufacturing processes of the semiconductor device according to the second embodiment, which is the cross-sectional view showing the manufacturing processes of the semiconductor device continued from FIG. 25;

FIG. 27 is a cross-sectional view showing manufacturing processes of the semiconductor device according to the second embodiment, which is the cross-sectional view showing the manufacturing processes of the semiconductor device continued from FIG. 26;

FIG. 28 is a cross-sectional view showing manufacturing processes of the semiconductor device according to the second embodiment, which is the cross-sectional view showing the manufacturing processes of the semiconductor device continued from FIG. 27;

FIG. 29 is a cross-sectional view showing manufacturing processes of the semiconductor device according to the second embodiment, which is the cross-sectional view showing the manufacturing processes of the semiconductor device continued from FIG. 28;

FIG. 30 is a cross-sectional view showing manufacturing processes of a semiconductor device according to an applied example of the second embodiment;

FIG. 31 is a cross-sectional view showing manufacturing processes of the semiconductor device according to the applied example of the second embodiment, which is the cross-sectional view showing the manufacturing processes of the semiconductor device continued from FIG. 30;

FIG. 32 is a cross-sectional view showing manufacturing processes of the semiconductor device according to the applied example of the second embodiment, which is the cross-sectional view showing the manufacturing processes of the semiconductor device continued from FIG. 31;

FIG. 33 is a cross-sectional view showing a substrate layer used in a semiconductor device according to a third embodiment;

FIG. 34 is a cross-sectional view showing a first configuration example of a substrate used for manufacturing the semiconductor device according to the third embodiment;

FIG. 35 is a cross-sectional view showing another example of the substrate used for manufacturing the semiconductor device according to the third embodiment;

FIG. 36 is a cross-sectional view showing a second configuration example of a substrate used for manufacturing the semiconductor device according to the third embodiment;

FIG. 37 is a cross-sectional view showing another example of the substrate used for manufacturing the semiconductor device according to the third embodiment; and

FIG. 38 is a schematic diagram showing a configuration of a railway vehicle according to a fourth embodiment.

### BEST MODE FOR CARRYING OUT THE INVENTION

Hereinafter, embodiments of the present invention will be described in detail based on the accompanying drawings. Note that components having the same function are denoted by the same reference symbols throughout all the drawings for describing the embodiments, and the repetitive description thereof will be omitted. Also, in the embodiments, the description for the same or similar portions is not repeated in principle. Also, in some drawings used in the embodiments, hatching is used even in a plan view so as to make the drawings easy to see.

Moreover, symbols “−” and “+” show relative concentrations of impurities, each conductivity type of which is n-type or p-type. For example, in the case of the n-type impurity, the impurity concentration becomes higher in the order of “n”, “n” and “n⁺”. Furthermore, in the present application, a substrate and an epitaxial layer (substrate layer) formed on the substrate are collectively referred to as “substrate” in some cases. In the semiconductor device of each embodiment, note that an element formation surface side is defined as an upper surface (front surface, first surface) and an opposite side to the element formation surface is defined as a lower surface (rear surface, second surface) in the substrate, substrate layer and respective layers and respective regions forming the semiconductor device.

### First Embodiment

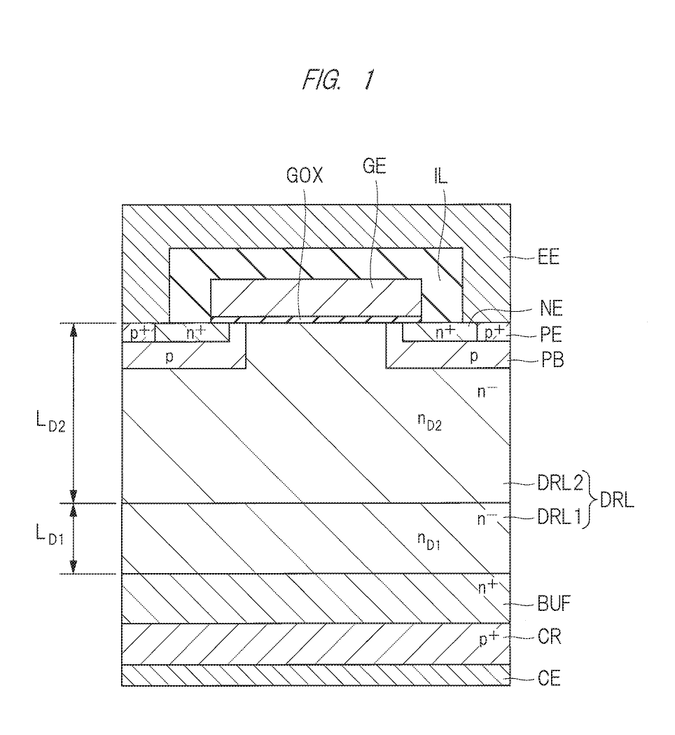

In the following, a semiconductor device of the present embodiment will be described in detail with reference to the drawings. FIG. 1 is a cross-sectional view showing a configuration of a semiconductor device according to the present embodiment. The semiconductor device of the present embodiment corresponds to an IGBT (Insulated Gate Bipolar Transistor). In particular, the semiconductor device uses SiC (silicon carbide) having a band gap of about three times as large in Si ratio as and a dielectric-breakdown electric field intensity of about ten times as large as those of Si (silicon).

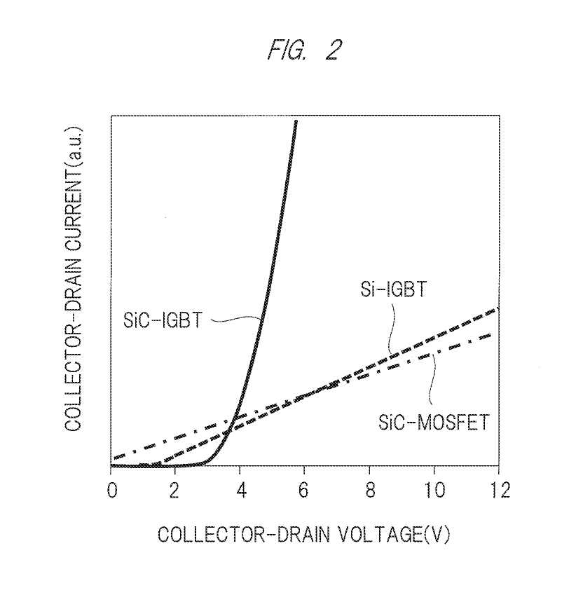

Such an IGBT (SiC-IGBT) using the SiC has very favorable characteristics more than those of an MOSFET (SiC-MOSFET) using SiC and an IGBT (Si-IGBT) using Si. FIG. 2 is a graph showing static characteristics obtained when each of Si-IGBT, SiC-MOSFET and SiC-IGBT is conducted. A vertical axis indicates collector-drain current (a.u.), and a horizontal axis indicates a collector-drain voltage (V).

SiC-IGBT and Si-IGBT are compared with each other. The SiC-IGBT has a built-in voltage of about 3 V, and the Si-IGBT has a built-in voltage of about 0.8 V. Therefore, a current value (a collector-drain current value) is larger in the Si-IGBT within a range in which the voltage value (the collector-drain voltage value) is up to about 4 V. However, in a range in which the voltage value is 4 V or larger, the resistance of the SiC-IGBT is lowered, and therefore, the current value becomes extremely large. This is because the SiC-IGBT has a film thickness of the drift layer that is smaller than (for example, about 1/10 of) a film thickness of the same of the Si-IGBT even when they are the same bipolar elements, which results in a large difference in the resistance of the drift layer. For example, at a breakdown voltage of 6.5 kV, while the film thickness of the drift layer in the Si-IGBT is about 650 μm, the film thickness of the same of the SiC-IGBT is about 65 μm. Moreover, SiC-MOSFET (metal-oxide-semiconductor field-effect transistor) and SiC-IGBT are compared with each other. Also in this case, in a range in which the voltage value is 4 V or larger, the resistance of the SiC-IGBT is lowered, and therefore, the current value becomes extremely large. This is because of a resistance reduction effect due to a minority carrier storage effect of the IGBT. In this manner, the SiC-IGBT has very favorable characteristics.

[Explanation of Configuration]

As shown in FIG. 1, the semiconductor device of the present embodiment has a collector region CR made of a p⁺-type semiconductor region having an upper surface (front surface, first surface) and a lower surface (rear surface, second surface) on the side opposite to the upper surface. On the upper surface of this collector region CR, a buffer layer BUF made of an n⁺-type semiconductor region is formed. Moreover, on the buffer layer BUF, a drift layer DRL made of an n⁻-type semiconductor region is formed. For example, the buffer layer BUF functions as a depletion stop layer under a reversed bias, and controls the injection efficiency of an anode on the rear side under a conduction mode in a forward direction.

This drift layer DRL has an n⁻-first drift region DRL1 and an n⁻-second drift region DRL2. The n -first drift region DRL1 is formed on the buffer layer BUF, and the n⁻-second drift region DRL2 is formed on the n⁻-first drift region DRL1. The concentration (nD1) of an n-type impurity in the n⁻-first drift region DRL1 is smaller (lower) than the concentration (nDB) of an n-type impurity in the buffer layer BUF. The concentration (nD2) of an n-type impurity in the n⁻-second drift region DRL2 is smaller than the concentration (nD1) of the n-type impurity in the n⁻-first drift region DRL1. That is, these concentrations have a relation of “the concentration (nDB) of the n-type impurity in the buffer layer BUF >the concentration (nD1) of the n-type impurity in the n⁻-first drift region DRL1>the concentration (nD2) of the n-type impurity in the n⁻-second drift region DRL2”. Moreover, the film thickness (LD2) of the n⁻-second drift region DRL2 is larger (thicker) than the film thickness (LD1) of the n⁻-first drift region DRL1. That is, the film thicknesses have a relation of “the film thickness (LD2) of the n⁻-second drift region DRL2>the film thickness (LD1) of the n⁻-first drift region DRL1”.

Inside the drift layer DRL (n⁻-second drift region DRL2), a P-type body region PB (also referred to as “p-type well region”) made of a p-type semiconductor region is formed. Moreover, inside this P-type body region PB, an N-type emitter region NE made of an n⁺-type semiconductor region is formed, and a P-type emitter region PE is formed so as to be made in contact with the N-type emitter region NE and the P-type body region PB.

Moreover, a gate insulating film GOX is formed so as to be made in contact along with the drift layer DRL (n⁻-second drift region DRL2), the P-type body region PB and the N-type emitter region NE, and a gate electrode GE is formed on the gate insulating film GOX. Furthermore, on the N-type emitter region NE and the P-type emitter region PE, an emitter electrode EE is formed. Between the gate electrode GE and the emitter electrode EE, an interlayer insulating film IL is formed. On the other hand, on the lower surface of the collector region CR, a collector electrode CE is formed.

In this case, in the present embodiment, a substrate layer is formed by the collector region CR, the buffer layer BUF and the drift layer DRL, and this substrate layer is made of silicon carbide as a main material. The “main material” means a material component that is contained at the largest amount among the constituent materials forming the substrate layer. For example, “silicon carbide as a main material” means that the materials of the substrate layer contain silicon carbide as the largest amount, and that a case containing other impurities is not excluded therefrom.

Each of the collector region CR and the P-type body region PB is a semiconductor region formed by introducing a p-type impurity (for example, aluminum (Al) or boron (B)) into silicon carbide. Moreover, each of the buffer layer BUF, the drift layer DRL and the N-type emitter region NE is a semiconductor region formed by introducing an n-type impurity (for example, nitrogen (N), phosphorus (P) or arsenic (As)) into silicon carbide.

while the concentration of the impurity of each of the semiconductor regions can be appropriately set, the concentration (nDB) of the n-type impurity in the buffer layer BUF is set to be, for example, less than 1×10¹⁹ cm³. The concentration (nD1) of the n-type impurity in the n⁻-first drift region DRL1 is set to be, for example, less than 5×10¹⁵ cm⁻³. The concentration (nD2) of the n-type impurity in the n⁻-second drift region DRL2 is set to be, for example, less than 2×10¹⁵ cm⁻³. Moreover, the concentration of the n-type impurity in the N-type emitter region NE is set to be, for example, equal to or larger than 1×10¹⁹ cm⁻³.

Moreover, the concentration of the p-type impurity in the P-type emitter region PE is set to be, for example, equal to or larger than 1×10¹⁹ cm⁻³. The concentration of the p-type impurity in the collector region CR is set to be, for example, equal to or larger than 5×10¹⁷ cm⁻³. Furthermore, the concentration of the p-type impurity in the P-type body region PB is set be, for example, equal to or larger than 1×10¹⁷ cm⁻³ but less than 5×10¹⁹ cm⁻³.

The gate insulating film GOX is formed of, for example, an insulating film such as a silicon oxide film, and the gate electrode GE is formed of, for example, a conductive film such as a polysilicon film. Moreover, the emitter electrode EE is made of metal (conductive film) such as aluminum (Al), titanium (Ti), nickel (Ni) or others, and is configured to be electrically connected to the P-type body region PB, the N-type emitter region NE and the P-type emitter region PE. An interlayer insulating film IL between the gate electrode GE and the emitter electrode EE is formed of, for example, an insulating film such as a silicon oxide film.

The collector electrode CE is provided in order to reduce a contact resistance caused when a semiconductor chip is mounted on a module. Moreover, the collector electrode CE is made of metal (conductive film) such as aluminum (Al), titanium (Ti), nickel (Ni), gold (Au), silver (Ag), or others. As the collector electrode CE, note that a conductive nitride film such as titanium nitride (TiN), tantalum nitride (TaN) or others may be used. Moreover, a stacked film of a nitride film and a metal film may also be used.

In this manner, in the present embodiment, the drift layer DRL is formed into a stacked structure having the n⁻-first drift region DRL1 and the n⁻-second drift region DRL2. Therefore, even when a high voltage is applied at the off-time of the semiconductor device (semiconductor element), the electric field of the front surface on the emitter region side can be lowered. Moreover, since a region where the carriers are stored can be ensured at the switching time, the noises can be reduced.

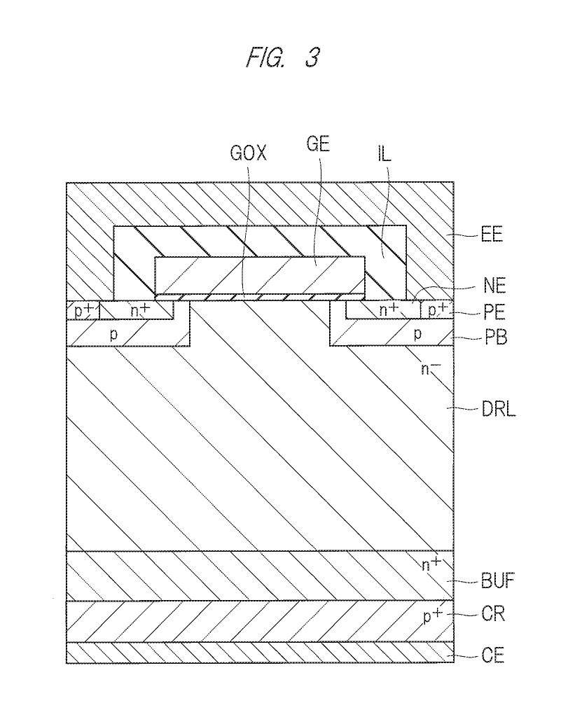

FIG. 3 is a cross-sectional view showing a configuration of a semiconductor device according to a comparative example of the present embodiment. In the semiconductor device of the comparative example shown in FIG. 3, the drift layer DRL is formed as a single layer. In other words, the semiconductor device of the comparative example corresponds to a semiconductor device in which a relation of “nD1=nD2” is satisfied in the semiconductor device of FIG. 1.

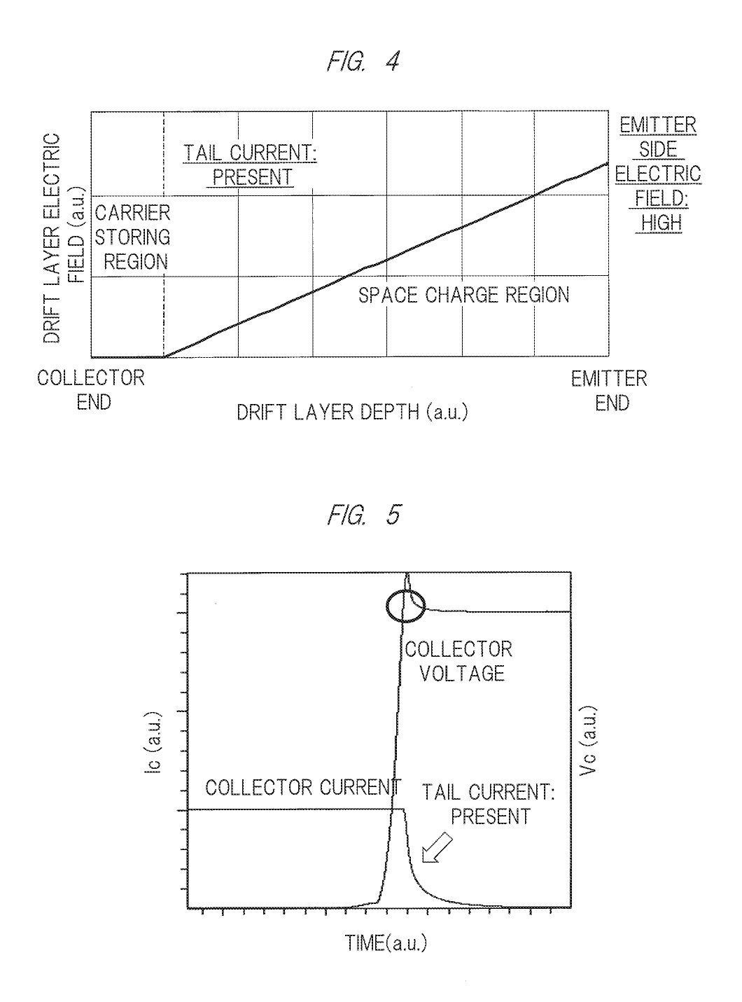

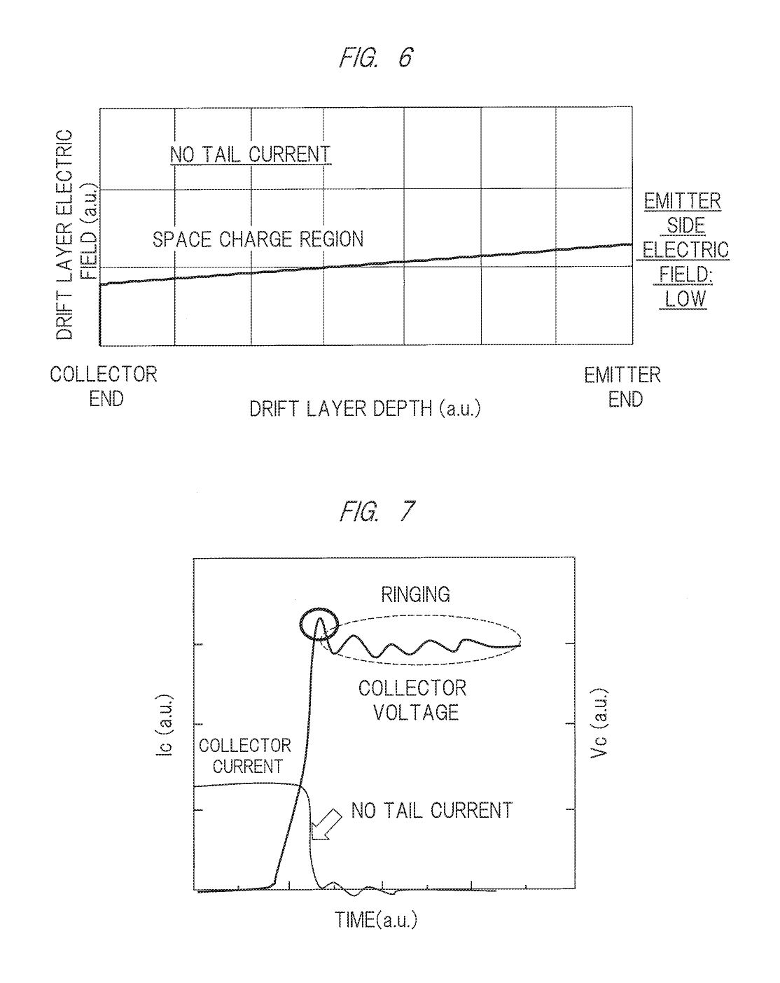

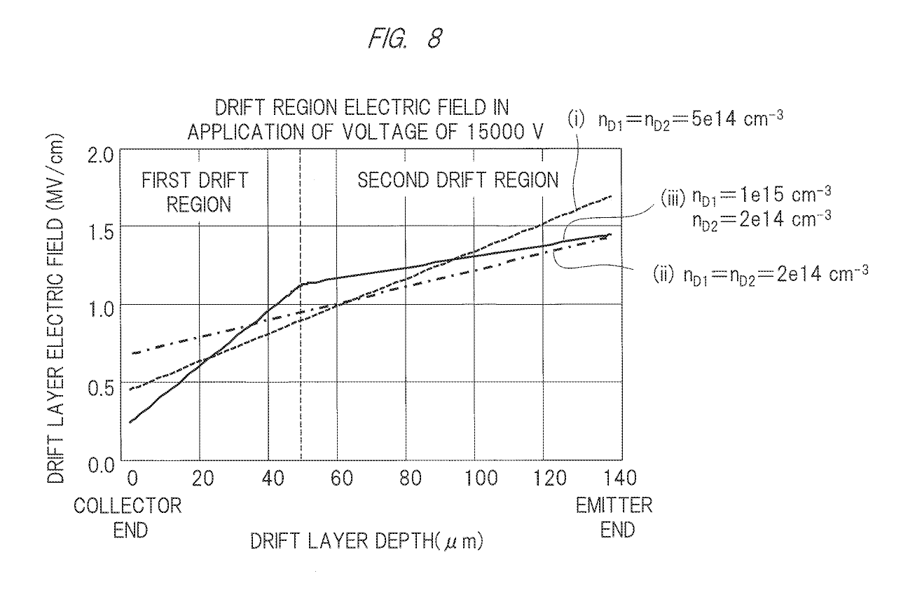

FIG. 4 is a conceptual diagram showing an internal electric field of a drift layer in the case of setting the drift layer at a high concentration in the semiconductor device of the comparative example. FIG. 5 is a conceptual diagram showing waveforms of a collector current and a collector voltage in the case of setting the drift layer at a high concentration in the semiconductor device of the comparative example. FIG. 6 is a conceptual diagram showing an internal electric field of a drift layer in the case of setting the drift layer at a low concentration in the semiconductor device of the comparative example. FIG. 7 is a conceptual diagram showing waveforms of a collector current and a collector voltage in the case of setting the drift layer at a low concentration in the semiconductor device of the comparative example.

In FIG. 4 and FIG. 6, a horizontal axis indicates adrift layer depth (a. u.), and a vertical axis indicates a drift layer electric field (a. u.). In a horizontal axis, a left side indicates the collector end (collector region side), and a right side indicates the emitter end (emitter region side). Moreover, in FIG. 5 and FIG. 7, a horizontal axis indicates time (a. u.), and a vertical axis indicates Ic (collector current, a. u.) and Vc (collector voltage, a. u.).

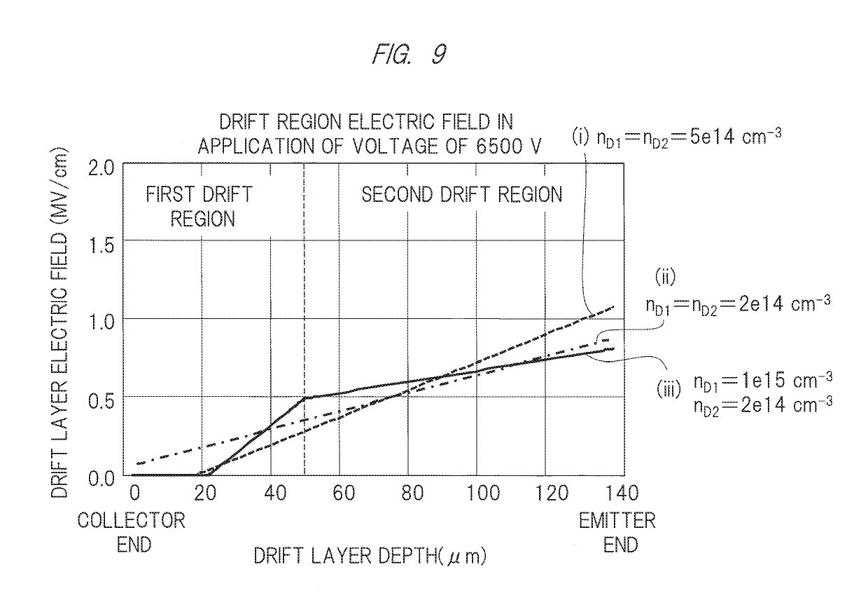

Moreover, each of FIG. 8 and FIG. 9 is a conceptual diagram showing a relation between a configuration of a drift layer and the internal electric field of the drift layer. FIG. 8 shows a state of the internal electric field at the time of application of a high voltage, and FIG. 9 shows an internal electric field in the drift layer at the time of operation. The high voltage described here is a voltage corresponding to the breakdown voltage (for example, about twice as large as the voltage at the time of operation) such as 15000 V (15 kV), and the voltage at the time of operation is 6500 V (6.5 kV). In FIG. 8 and FIG. 9, a horizontal axis indicates the drift layer depth (μm), and a vertical axis indicates the drift layer electric field (MV/cm).

As described above, “nD1” represents the concentration of the n-type impurity in the n⁻-first drift region DRL1, and “nD2” represents the concentration of the n-type impurity in the n⁻-second drift region DRL2. Moreover, “LD1” represents a film thickness (thickness) of the n⁻-first drift region DRL1, and “LD2” represents a film thickness (thickness) of the n⁻-second drift region DRL2. FIG. 8 and FIG. 9 show a relation of “LD1=50 μm and LD2=90 μm”. In FIG. 8 and FIG. 9, a graph (i) (one-dot chain line) indicates the internal electric field (drift layer electric field) of the drift layer in a case of a relation “nD1=nD2=5×10¹⁴(5e14) cm³” in FIG. 1, that is, a case in which the impurity concentration of the drift layer DRL that is the single layer shown in FIG. 3 is set to a comparatively high concentration (5×10¹⁴ cm³). Moreover, a graph (ii) (chain line) indicates the internal electric field (drift layer electric field) of the drift layer in a case of a relation “nD1=nD2=2×10¹⁴ (2e14) cm⁻³” in FIG. 1, that is, a case in which the impurity concentration of the drift layer DRL that is the single layer shown in FIG. 3 is set to a comparatively low concentration (2×10¹⁴ cm⁻³). Furthermore, a graph (iii) (solid line) is a graph relating to the present embodiment. That is, this graph indicates the internal electric field (drift layer electric field) of the drift layer in a case of a relation of “nD1=1×10¹⁵ (1e15) cm³ and nD2 =2×10¹⁴(2e14)cm³” in FIG. 1, that is, a case in which the drift layer DRL has a stacked structure (DRL1, DRL2).

As shown in the graph (i) (one-dot chain line), in the case in which the drift layer DRL that is the single layer is used and in which the impurity concentration is set to a comparatively high concentration (nD1=nD2=5e14 cm⁻³), when a voltage of 6500 V is applied between the collector electrode and the emitter electrode of the semiconductor device, a region as deep as about 20 μm where no electric field is applied is left in the drift layer (FIG. 9). Thus, a tail current flows at the time of switching. On the other hand, when a voltage of 15000 V is applied between the collector electrode and the emitter electrode of the semiconductor device, a high electric field as high as about 1.69 MV/cm is generated on the surface on the emitter region side (FIG. 8).

As one of methods for eliminating the application of such a high electric field onto the emitter region side, a method of lowering the impurity concentration of the drift layer DRL is proposed. For example, in the case of “nD1=nD2=2e14”, when the voltage of 15000 V is applied between the collector electrode and the emitter electrode of the semiconductor device, the electric field of the surface on the emitter region side is lowered down to about 1.44 MV/cm (FIG. 8) as shown in the graph (ii) (chain line). However, in this case, when the voltage of 6500 V is applied between the collector electrode and the emitter electrode of the semiconductor device, any region where no electric field is applied is not left in the drift layer (FIG. 9). Therefore, no tail current flows at the time of switching.

On the other hand, in the case in which the drift layer DRL has the stacked structure (DRL1, DRL2) as in the present embodiment, when the voltage of 15000 V is applied between the collector electrode and the emitter electrode of a semiconductor device, the electric field of the surface on the emitter region side is lowered down to about 1.44 MV/cm (FIG. 8) as shown in the graph (iii) (solid line). Meanwhile, when the voltage of 6500 V is applied between the collector electrode and the emitter electrode of the semiconductor device, a region as deep as about 20 μm where no electric field is applied is left in the drift layer (FIG. 9). Thus, the tail current flows at the time of switching.

In this manner, according to the present embodiment, when a high voltage is applied, the electric field of the surface of the drift layer on the emitter region side can be lowered, and the noises can be reduced because the tail current flows at the time of switching.

That is, as shown in FIG. 4 and FIG. 5, when the impurity concentration of the drift layer DRL that is the single layer is comparatively high, while the electric field on the surface on the emitter region side becomes high (FIG. 4) , the tail current is generated in the collector current so that ringing of the collector voltage can be prevented.

That is, as shown in FIG. 5, even when the collector voltage changes from 0 V to a power-supply voltage (threshold voltage) , a collector current referred to as the tail current is allowed to flow for a certain period of time. This is because, when the power-supply voltage is applied, a space charge region is terminated but a carrier storage region is left inside the drift layer in the IGBT, so that the stored carriers continuously flow. However, in order to leave the stored carriers in the drift layer when such a power-supply voltage is applied, it is required to increase the concentration of the drift layer to be a certain concentration or higher . On the other hand, if the concentration of the drift layer increases, when a high voltage corresponding to its breakdown voltage is applied to the semiconductor device, the electric field on the emitter region side becomes undesirably high.

When the Si-IGBT is replaced by the SiC-IGBT, although the SiC itself has a dielectric-breakdown electric field that is 10 times as high as Si, a dielectric-breakdown electric field of a portion on the emitter region side such as a gate insulating film is unchanged because the gate insulating film is made of a material similar to the material in the case of the Si-IGBT. For example, although the drift layer of the SiC-IGBT withstands an electric field of 2.0 MV/cm, an electric field of about 5.3 MV/cm is applied to the gate insulating film (such as the silicon oxide film) that is made in contact with the drift layer because of a difference in the dielectric constant from SiC, and therefore, the dielectric-breakdown electric field is exceeded.

Meanwhile, as shown in FIG. 6 and FIG. 7, when the impurity concentration is comparatively low in the drift layer DRL that is the single layer, while the electric field on the surface of the emitter region side can be suppressed to be low (FIG. 6), no tail current is generated in the collector current, and therefore, the ringing (noises) of the collector voltage is generated.

That is, when the concentration of the drift layer is lowered as shown in FIG. 6 in order to solve the problem that is the generation of the high electric field on the emitter region side when the high voltage corresponding to the breakdown voltage is applied, the region where the carriers are stored at the time of application of the power-supply voltage is lost, a waveform at the time of switching is disordered, and therefore, there is a possibility in generation of the noises (high frequency noises) (FIG. 7).

In this manner, there is a trade-off relation between the noise reduction at the time of switching and the reduction of the electric field on the emitter region side.

On the other hand, the drift layer DRL has the stacked structure (DRL1, DRL2) in the present embodiment, so that, when the high voltage is applied, the electric field on the emitter region side can be lowered, and the noises can be reduced because the tail current flows at the time of switching as described above.

In order to lower the electric field on the emitter region side in the application of the high voltage by increasing the concentration of the drift layer DRL, it is required to satisfy a relation of “nD1>nD2” in the concentration (nD1) of the n-type impurity in the n⁻-first drift region DRL1 and the concentration (nD2) of the n-type impurity in the n⁻-second drift region DRL2.

Moreover, since the high concentration of the drift layer DRL behaves so as to prevent the minority carrier storage effect, it is preferable to thin the n⁻-second drift region DRL2 in order to prevent the deterioration of the resistance at the time of conduction. For this reason, it is required to at least make the film thickness (LD1) of the n⁻-first drift region DRL1 to be smaller (thinner) than the film thickness (LD2) of the n⁻-second drift region DRL2 (LD1<LD2).

Note that the n⁻-second drift region DRL2 may have a stacked structure while the n⁻-second drift region DRL2 is the single layer in the semiconductor device shown in FIG. 1. However, it is required to make the total of film thicknesses of the plurality of semiconductor regions forming the n⁻-second drift region DRL2 to be larger (thicker) than the film thickness of the n⁻-first drift region DRL1, and it is required in the n⁻-second drift region DRL2 to make the concentration of the n-type impurity of the semiconductor region that is made in contact with the n⁻-first drift region DRL1 to be smaller (lower) than the concentration (nD1) of the n-type impurity in the n⁻-first drift region DRL1.

Moreover, in the semiconductor device shown in FIG. 1, a so-called n-type SiC-IGBT has been described as an example. However, a p-type SiC-IGBT may be also applicable. Furthermore, in the semiconductor device shown in FIG. 1, SiC is used as a wide band- gap semiconductor. However, another wide band-gap semiconductor such as GaN may be also used. That is, not only the SiC-IGBT but also GaN-IGBT may be applicable.

[Explanation of Operation]

An operation of the semiconductor device (SiC-IGBT) according to the present embodiment will be explained. First, an operation for turning on the IGBT will be explained. In FIG. 1, by application of a sufficient positive voltage between the gate electrode GE and the emitter region ER, the MOSFET is turned on so that the emitter region ER and the drift layer DRL are conducted to each other through a channel formed in the P-type body region PB. In this case, a forward bias state is generated between the collector region CR and the buffer layer BUF (drift layer DRL), so that holes are injected from the collector region CR to the drift layer DRL through the buffer layer BUF. Successively, electrons equivalent to the positive charges of the holes injected to the drift layer DRL gather to the drift layer DRL. Thus, the reduction in the resistance of the drift layer DRL (conductivity modulation) is caused, so that the IGBT is turned on.

A joint voltage between the collector region CR and the drift layer DRL (buffer layer BUF) is added to the ON-voltage. However, since the resistance value of the drift layer DRL is lowered by one or more digits by the conductivity modulation, the IGBT has the ON-voltage that is lower than that of the power MOSFET under such a high breakdown voltage that the resistance value of the drift layer DRL occupies most of the ON-resistance. Therefore, it can be understood that the IGBT is an effective device for increasing the breakdown voltage. That is, in the power MOSFET, it is required to thick the epitaxial layer becoming the drift layer in order to increase the breakdown voltage. However, in this case, the ON-resistance also increases. On the other hand, in the IGBT, even when the drift layer DRL is thickened in order to increase the breakdown voltage, the conductivity modulation occurs at the time of the turning-ON operation in the IGBT. That is, in the ON-state of the IGBT, when a voltage is applied to the collector electrode CE so as to be equal to or higher than a built-in voltage of the p-n junction, the holes are injected from the collector side, and the electrons are also injected from the emitter region side, so that the electrons and holes with a plasma state are stored in the drift layer. This phenomenon is referred to as “minority carrier storage effect”. By this effect, the ON-resistance of the IGBT can be lower than that of the power MOSFET. That is, according to the IGBT, a device having a lower ON-resistance than that of the power MOSFET even in an attempt to increase the breakdown voltage can be achieved.

Next, an operation for turning off the IGBT will be explained. When the voltage between the gate electrode GE and the emitter region ER is lowered, the MOSFET is turned off. In this case, the electron injection from the emitter electrode EE to the drift layer DRL is stopped, the lifetimes of the already-injected electrons are over, and the electrons are reduced. The remaining electrons and holes directly flow out toward the collector region CR side and the emitter electrode EE side, respectively. At the time of the completion of the flow out, the IGBT is turned off. In this manner, the IGBT can be turned on and off. A current that flows at the time of the OFF operation (switching) is the above-described tail current. In this manner, at the time of switching, it is required to store and discharge the carriers, and therefore, a larger loss is generated than that of the power MOSFET. However, the stored carriers form the tail current so as to behave a buffering function, and therefore, the generation of the noises at the time of switching can be suppressed.

[Explanation of Manufacturing Method]

Next, manufacturing processes of the semiconductor device of the present embodiment will be explained, and the configuration of the semiconductor device of the present embodiment is more clearly described.

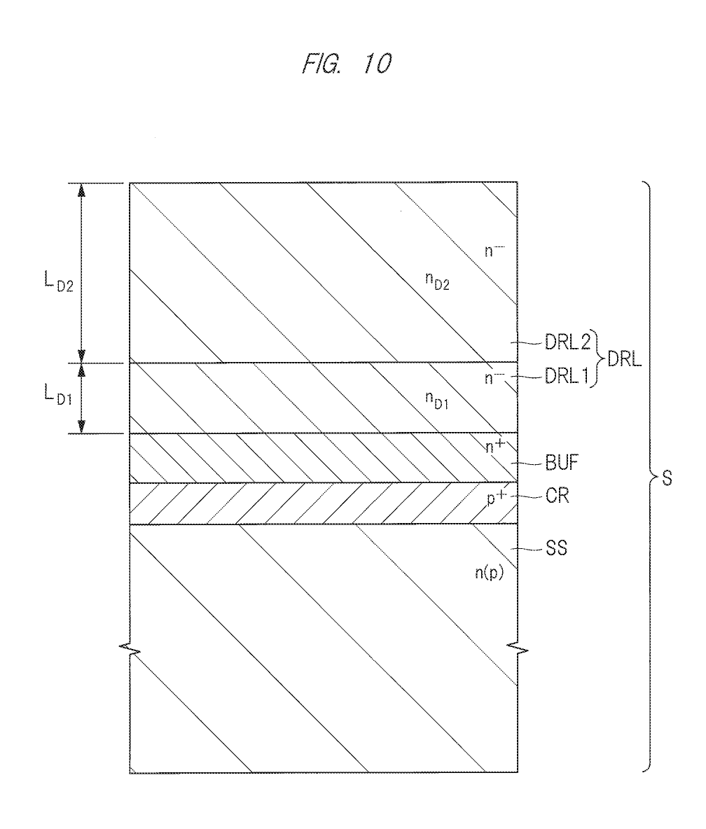

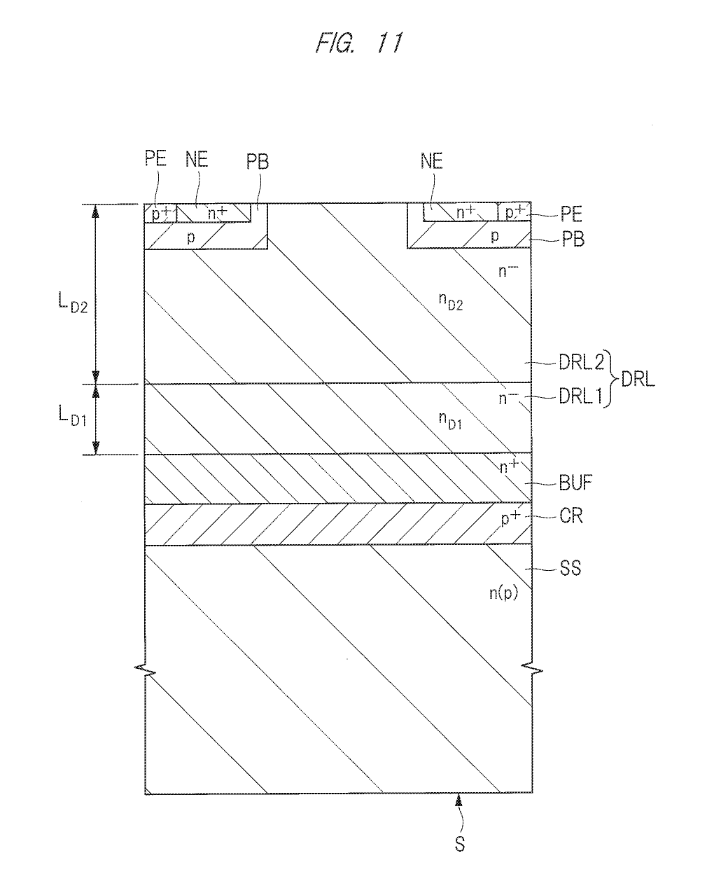

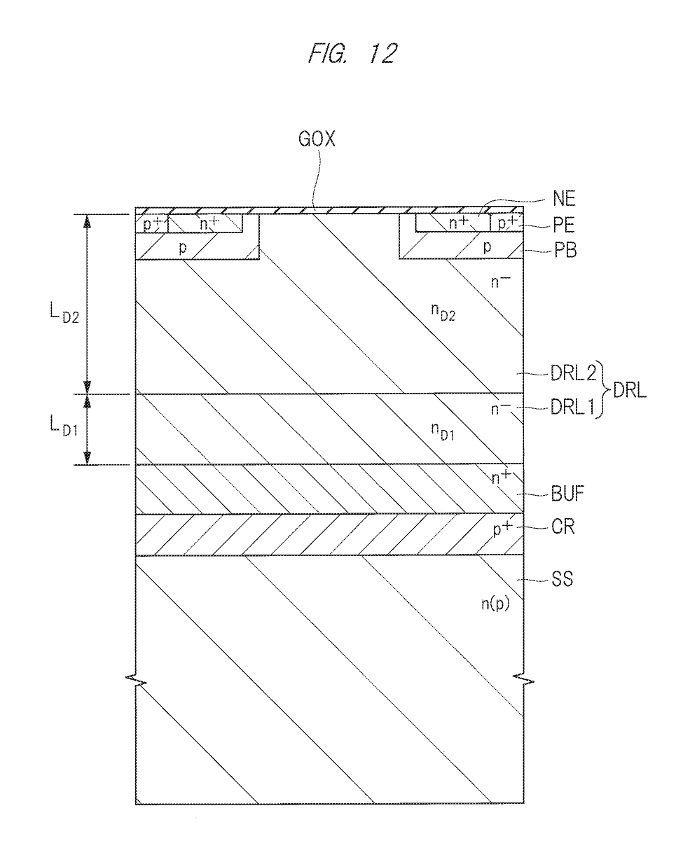

Each of FIG. 10 to FIG. 17 is a cross-sectional view showing the manufacturing processes of the semiconductor device of the present embodiment.

First, as shown in FIG. 10, a substrate “S” containing SiC as a main material is prepared. This substrate “S” has:, for example, a support substrate (base member part) “SS” composed of an n-type or p-type semiconductor layer having a front surface and a rear surface on the side opposite to the front surface; and a substrate layer (epitaxial layer) formed on the front surface of the support substrate “SS”. The substrate layer has: a collector region CR made of a p-type semiconductor region formed on the front surface of the support substrate SS; a buffer layer BUF made of an n-type semiconductor layer formed on the corrector region CR; and a drift layer DRL made of an n-type semiconductor layer formed on the buffer layer BUF.

This drift layer DRL has an n⁻-first drift region DRL1 and an n⁻-second drift region DRL2. Moreover, there is a relation of “nDB>nD1>nD2” among the concentration (nDB) of the n-type impurity in the buffer layer BUF, the concentration (nD1) of the n-type impurity in the n⁻-first drift region DRL1 and the concentration (nD2) of the n-type impurity in the n⁻-second drift region DRL2. Moreover, there is a relation of “LD1<LD2” between the film thickness (LD1) of the n⁻-first drift region DRL1 and the film thickness (LD2) of the n⁻-second drift region DRL2 . Such a substrate “S” is prepared. A method of manufacturing this substrate “S” will be explained in a third embodiment to be described later.

Next, as shown in FIG. 11, on the exposed surface side of the drift layer DRL (n⁻-second drift region DRL2), a P-type body region PB, an N-type emitter region NE and a P-type emitter region PE are formed. The P-type body region PB is formed by, for example, an ion implantation method. For example, the P-type body region PB is formed by introducing a p-type impurity to the drift layer DRL (SiC) while using a mask film (not shown) having an opening in the formation region of the P-type body region as a mask. As the mask film, for example, an SiO₂ (silicon oxide) film, a photoresist film or others is used. The N-type emitter region NE and the P-type emitter region PE are formed by, for example, the ion implantation method. For example, the P-type emitter region PB is formed by introducing a p-type impurity to the drift layer DRL (SiC) while using a mask film (not shown) having an opening in the formation region of the P-type emitter region as a mask. Moreover, for example, the N-type emitter region NE is formed by introducing an n-type impurity to the drift layer DRL (SiC) while using a mask film (not shown) having an opening in the formation region of the N-type emitter region as a mask. After this, a heating treatment for activating the impurity injected to each of the regions is performed. As the heating treatment, a heating process at a temperature of 1500 degrees or more for about 0.5 to 3 minutes is performed.

Next, as shown in FIG. 12, a gate insulating film GOX is formed on the P-type body region PB, the N-type emitter region NE, the P-type emitter region PE and the drift layer DRL (n⁻-second drift region DRL2). As the gate insulating film GOX, for example, a silicon oxide film is formed by a CVD (Chemical Vapor Deposition) method. As the gate insulating film GOX, not the silicon oxide film but another insulating film such as a silicon oxynitride film may also be used. Moreover, a high dielectric constant film such as a hafnium oxide film, an alumina film or others, may be also used. These films can be formed by the CVD method. Furthermore, the gate insulating film GOX may be formed by not the CVD method but a thermal oxidizing method, a wet oxidizing method, a dry oxidizing method or others.

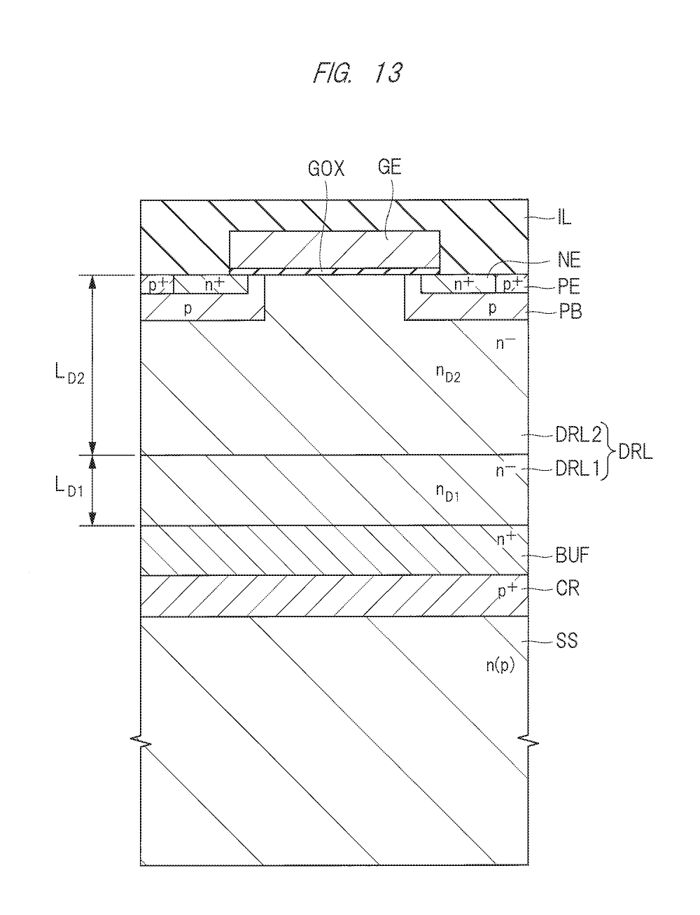

Next, as shown in FIG. 13, on the gate insulating film GOX, a gate electrode GE is formed. For example, a polysilicon film is formed on the gate insulating film GOX by the CVD method. Note that an amorphous silicon film may be formed first, and then, this film may be transformed into a polysilicon film by a subsequent heating treatment. Next, by patterning the polysilicon film, the gate electrode GE is formed. For example, by using a photolithography technique, a photoresist film covering the formation region of the gate electrode is formed on the polysilicon film. The gate electrode GE is formed by etching the polysilicon film while using this photoresist film as a mask. At this time, the insulating film GOX that is the lower layer may be patterned into the same shape as that of the gate electrode GE. The gate electrode GE is disposed on the N-type emitter region NE, the P-type body region PB and the drift layer DRL (n⁻-second drift region DRL2) through the gate insulating film GOX.

Next, an interlayer insulating film IL is formed on the gate electrode GE, the N-type emitter region NE and the P-type emitter region PE. As the interlayer insulating film IL, for example, a silicon oxide film is formed by the CVD method.

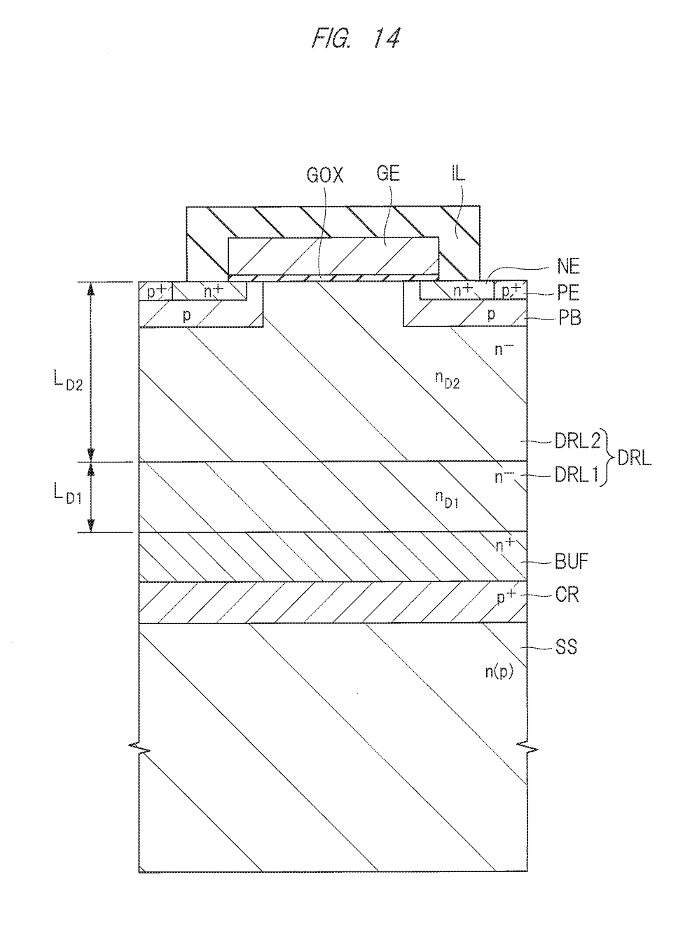

Next, as shown in FIG. 14, the interlayer insulating film IL on the N-type emitter region NE and the P-type emitter region PE is etched. For example, on the interlayer insulating film IL, a photoresist film having an opening in the connection region of the emitter electrode is formed. By etching the interlayer insulating film IL while using this photoresist film as a mask, the N-type emitter region NE and the P-type emitter region PE are exposed. The exposed regions of these N-type emitter region NE and the P-type emitter region PE become contact holes.

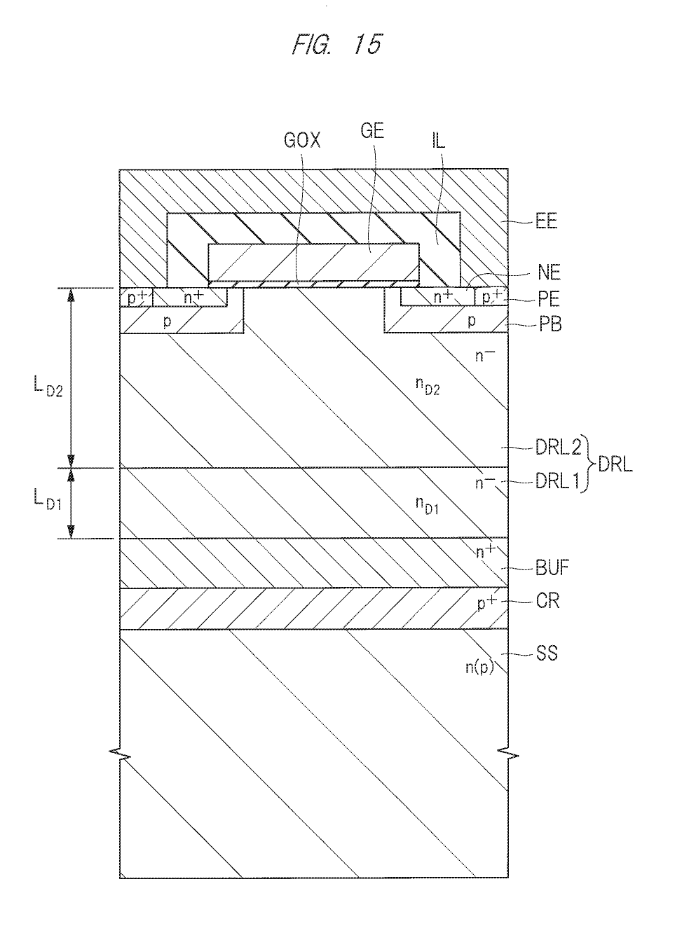

Next, as shown in FIG. 15, an emitter electrode EE is formed on the exposed regions of the N-type emitter region NE and the P-type emitter region PE as well as on the interlayer insulating film IL. For example, as the emitter electrode EE, an Al film is formed by a sputtering method. After this, the Al film is patterned, if necessary.

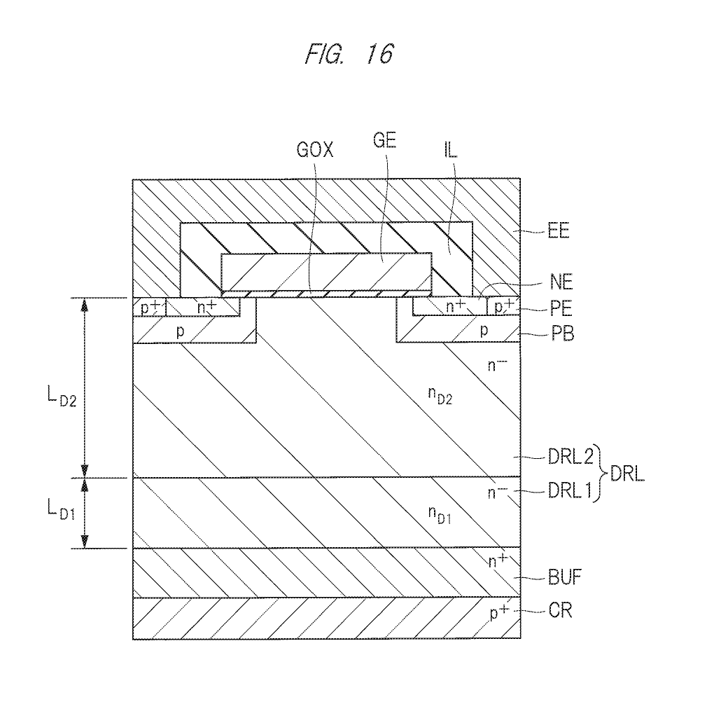

Next, as shown in FIG. 16, the support substrate SS of the substrate S is removed. Thus, the collector region CR is exposed. For example, the support substrate SS is removed by polishing the support substrate SS of the substrate S while taking the rear surface side of the support substrate SS as the upper side.

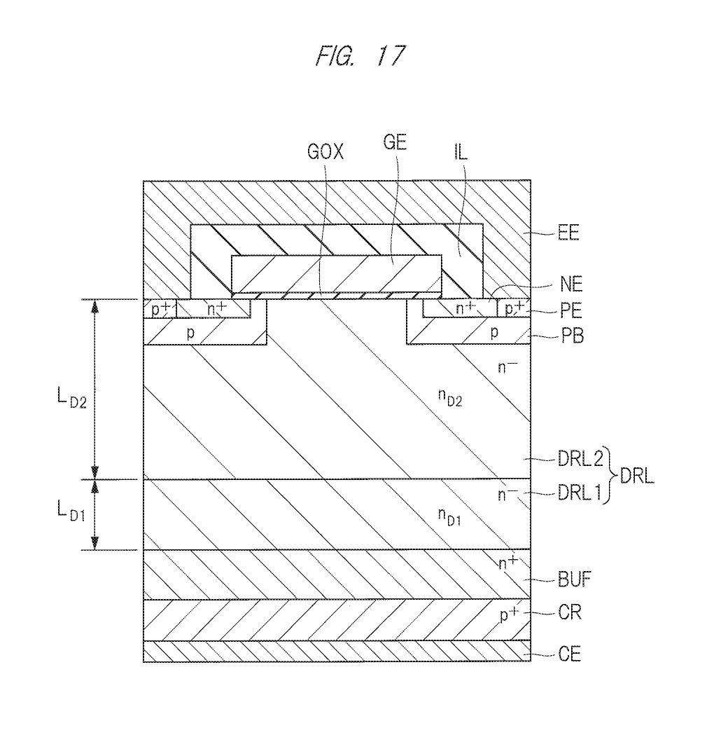

Next, as shown in FIG. 17, a collector electrode CE is formed on the exposed surface (lower surface) of the collector region CR. For example, an Ni film is formed by the sputtering method on the exposed surface of the collector region CR while taking the exposed surface (lower surface) of the collector region CR as the upper side. Thus, the collector electrode CE made of the Ni film is formed.

### Applied Example

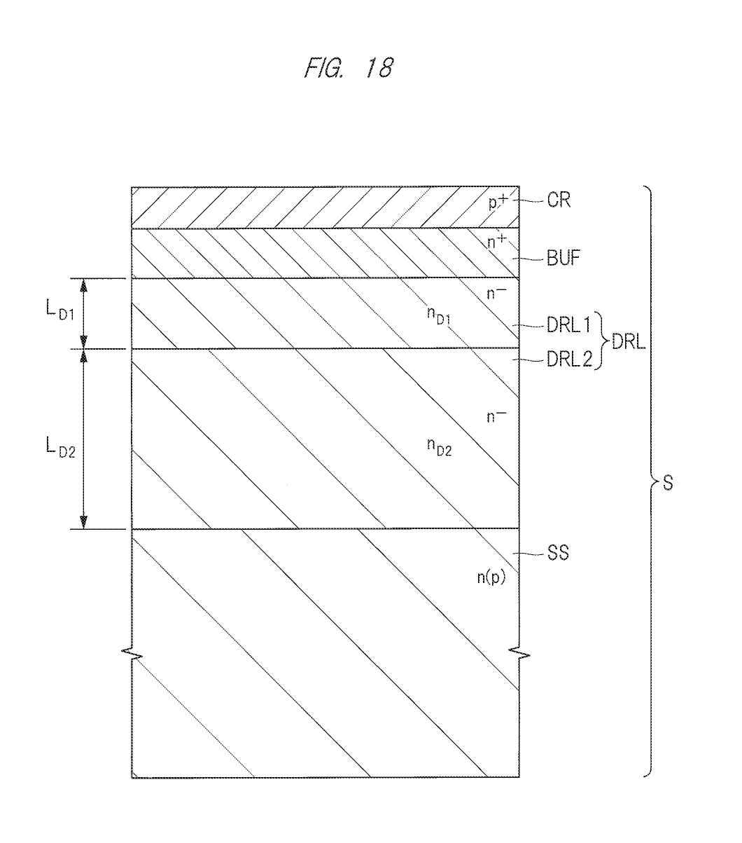

In the above-described manufacturing processes, for example, the substrate S as shown in FIG. 10 is used, the substrate being formed by sequentially stacking the collector region CR, the buffer layer BUF and the drift layer DRL on the support substrate SS. However, a substrate having another structure may be also used. Each of FIG. 18 to FIG. 20 is a cross-sectional view showing manufacturing processes of a semiconductor device according to an applied example of the present embodiment.

For example, as shown in FIG. 18, the substrate S containing SiC as a main material has a support substrate (base substrate part) SS made of an n-type or p-type semiconductor layer, a drift layer DRL made of an n-type semiconductor layer formed on the front surface of the support substrate SS, a buffer layer BUF made of an n-type semiconductor layer formed on the drift layer DRL and a collector region CR made of a p-type semiconductor region formed on the buffer layer BUF.

This drift layer DRL has an n⁻-first drift region DRL1 formed on the support substrate SS and an n⁻-second drift region DRL2 formed on the n⁻-first drift region. Moreover, there is a relation of “nDB>nD1>nD2” among the concentration (nDB) of the n-type impurity in the buffer layer BUF, the concentration (nD1) of the n-type impurity in the n⁻-first drift region DRL1 and the concentration (nD2) of the n-type impurity in the n⁻-second drift region DRL2. Moreover, there is a relation of “LD1<LD2” between the film thickness (LD1) of the n⁻-first drift region DRL1 and the film thickness (LD2) of the n⁻-second drift region DRL2. Such a substrate “S” is prepared. A method of manufacturing this substrate “S” will be explained in a third embodiment to be described later.

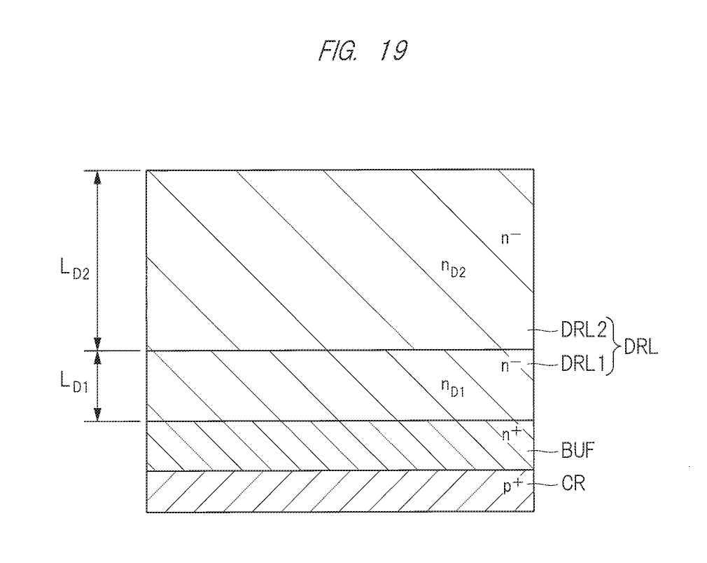

Next, the support substrate SS is removed by polishing the support substrate SS of the substrate S while taking the rear surface side of the support substrate SS as the upper side. Thus, the upper surface of the drift layer DRL (n⁻-second drift region DRL2) is exposed (FIG. 19).

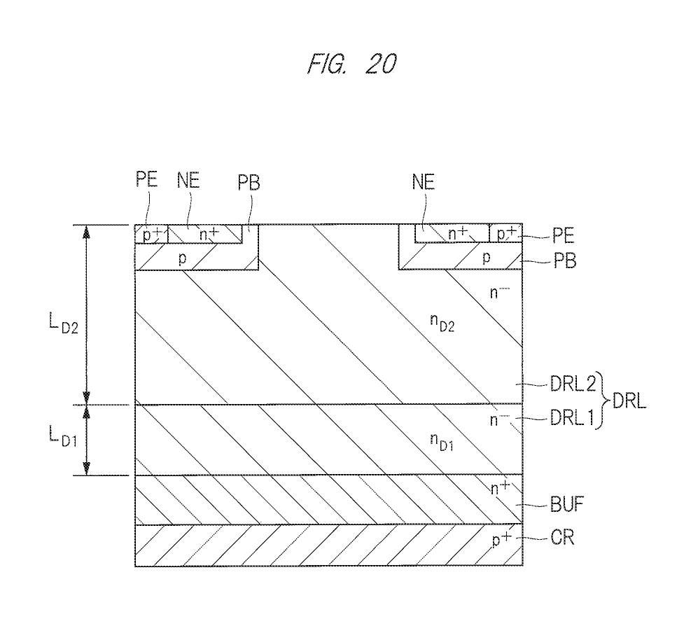

Next, as shown in FIG. 20, a P-type body region PB, an N-type emitter region NE and a P-type emitter region PE are formed on the exposed surface side of the drift layer DRL (n⁻-second drift region DRL2). These regions can be formed by, for example, the ion implantation method as similar to the above-described manufacturing processes. After this, a gate insulating film GOX, agate electrode GE, an interlayer insulating film IL and an emitter electrode EE are sequentially formed on the drift layer DRL or others as similar to the above-described manufacturing processes, and besides, a collector electrode CE is formed below the collector region CR.

### Second Embodiment

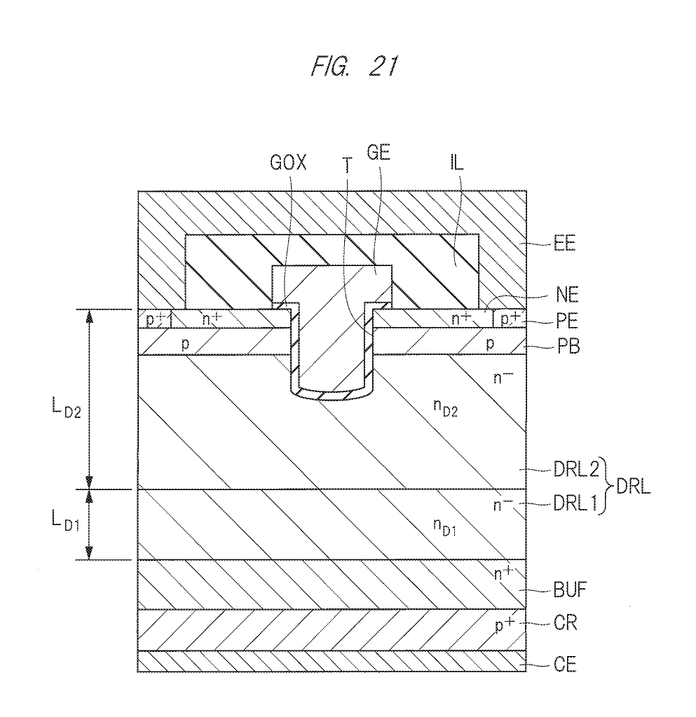

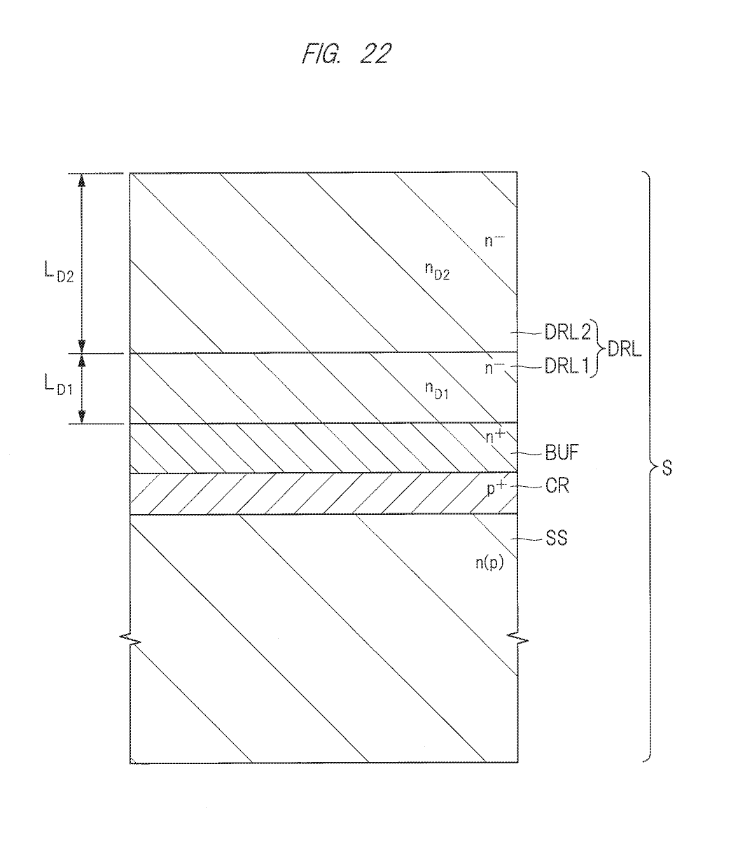

In the following, a semiconductor device of the present embodiment will be described in detail with reference to the drawings. FIG. 21 is a cross-sectional view showing a configuration of a semiconductor device according to the present embodiment. The semiconductor device of the present embodiment corresponds to an IGBT. In particular, the semiconductor device uses SiC having a band gap of about three times as large in Si ratio as and a dielectric-breakdown electric field intensity of about ten times as large as those of Si. Moreover, in the present embodiment, a so-called trench-type gate electrode is adopted. Even when such a trench-type gate electrode is adopted, the SiC-IGBT has very favorable characteristics.

[Explanation of Configuration]

The semiconductor device of the present embodiment is the same as that of the first embodiment except for the configuration of the gate electrode GE.

As shown in FIG. 21, in the semiconductor device of the present embodiment, a collector region CR, a buffer layer BUF formed on the collector region, and a drift layer DRL on the buffer layer are formed. Moreover, a substrate layer is formed by the collector region CR, the buffer layer BUF and the drift layer DRL, and the substrate layer contains SiC as a main material.

In addition, this drift layer DRL has an n⁻-first drift region DRL1 and an n⁻-second drift region DRL2. The n⁻-first drift region DRL1 is formed on the buffer layer BUF, and the n⁻-second drift region DRL2 is formed on the n⁻-first drift region DRL1. The concentration (nD1) of an n-type impurity in the n⁻-first drift region DRL1 is smaller (lower) than the concentration (nDB) of an n-type impurity in the buffer layer BUF. The concentration (nD2) of an n-type impurity in the n⁻-second drift region DRL2 is smaller than the concentration (nD1) of the n-type impurity in the n⁻-first drift region DRL1. That is, these concentrations have a relation of “the concentration (nDB) of the n-type impurity in the buffer layer BUF >the concentration (nD1) of the n-type impurity in the n⁻-first drift region DRL1>the concentration (nD2) of the n-type impurity in the n⁻-second drift region DRL2”. Moreover, the film thickness (LD2) of the n⁻-second drift region DRL2 is larger (thicker) than the film thickness (LD1) of the n⁻-first drift region DRL1. That is, the film thicknesses have a relation of “the film thickness (LD2) of the n⁻-second drift region DRL2>the film thickness (LD1) of the n⁻-first drift region DRL1”.

Above the drift layer DRL (n⁻-second drift region DRL2), a P-type body region PB (also referred to as “p-type well region”) made of a p-type semiconductor region is formed. Moreover, on this P-type body region PB, an N-type emitter region NE made of an n⁺-type semiconductor region is formed, and a P-type emitter region PE is formed so as to be made in contact with the N-type emitter region NE and the P-type body region PB.

Moreover, a trench (groove) “T” which reaches the drift layer DRL so as to be deeper than the P-type body region PB is formed. This trench “T” has a surface perpendicular to the front surface of the drift layer DRL (substrate front surface), the surface being made in contact with the N-type emitter region NE, the P-type body region PB and the n⁻-second drift region DRL2. Furthermore, a gate insulating film GOX is formed on an inner wall of the trench “T”, and the gate electrode GE is formed so as to bury the inside of the trench “T” through the gate insulating film GOX.

In the lower surface of the collector region CR, a collector electrode CE is formed.

As constituent materials of the respective portions of the semiconductor device of the present embodiment, the same materials as those of the first embodiment can be used.

In this manner, in the present embodiment, the drift layer DRL is formed so as to have the stacked structure having the n⁻-first drift region DRL1 and the n⁻-second drift region DRL2. Therefore, as explained in the first embodiment in detail, even if the high voltage is applied when the semiconductor device (semiconductor element) is turned off, the electric field on the surface of the emitter region side can be lowered. Moreover, at the time of switching, the region where the carriers are stored can be ensured, and therefore, the noises can be reduced.

Particularly, the case of adoption of the trench-type gate electrode has an effect causing the smaller channel resistance than that in a case of adoption of a so-called planar-type gate electrode. However, the bottom portion of the trench is exposed to the high electric field when the high voltage is applied. For this reason, the electric field can be moderated by decreasing the impurity concentration of the drift layer. However, by only simply decreasing the concentration, the region where the carriers are stored is lost at the time of switching as described above, and the noises are undesirably generated.

In this manner, when the trench-type gate electrode is adopted, the bottom portion of the trench is exposed to the high electric field, and therefore, the effect for moderating the electric field is large. For example, in the graph (i) in FIG. 8, an electric field of about 1.69 MV/cm is generated on the emitter region side. At this time, an electric field that is 2.63 times as large as a ratio in a dielectric constant between the gate oxide film and SiC is applied to the gate insulating film, and therefore, it is estimated that an electric field of about 4.5 MV/cm is applied. This is close to about 5 MV/cm that is the dielectric-breakdown electric field of the oxide film, and therefore, there is a risk of occurrence of dielectric breakdown at a portion such as a corner of the trench at which the electric field is concentrated. Meanwhile, in the graph (iii) in FIG. 8, even by the same calculation, the electric field to be applied to the gate insulating film is estimated to 3.9 MV/cm. In this manner, the large electric field moderating effect as much as 0.6 MV/cm can be expected.

[Explanation of Operations]

The operations of the semiconductor device (SiC-IGBT) of the present embodiment are the same as those of the first embodiment.

[Explanation of Manufacturing Method]

Next, manufacturing processes of the semiconductor device of the present embodiment will be explained, and the configuration of the semiconductor device of the present embodiment is more clearly described. Note that the detailed explanations for the similar processes to those of the first embodiment will be omitted.

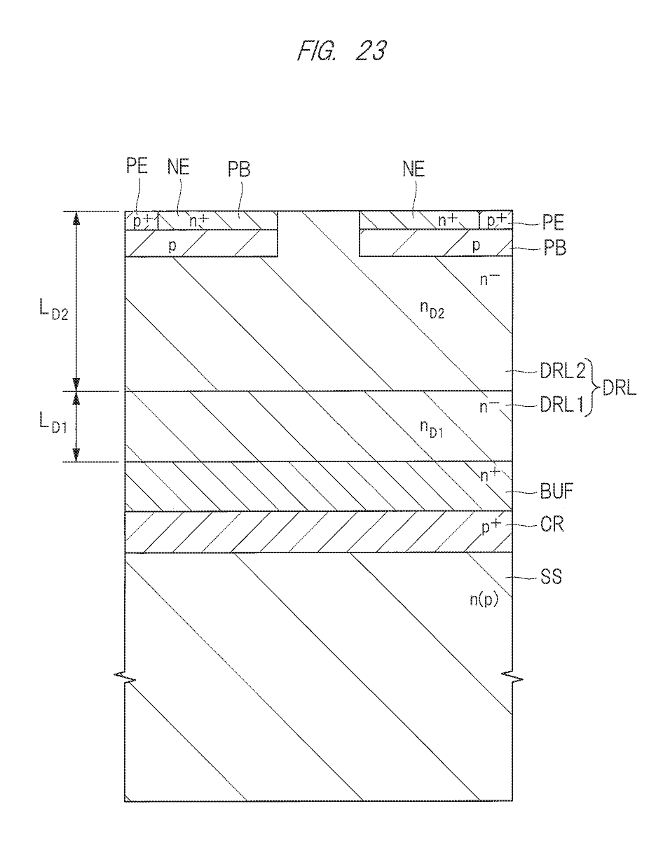

Each of FIG. 22 to FIG. 29 is a cross-sectional view showing the manufacturing processes of the semiconductor device of the present embodiment.

First, as shown in FIG. 22, as a substrate “S” containing SiC as a main material, the substrate “S” having: a support substrate (base member part) “SS” composed of an n-type or p-type semiconductor layer; and a substrate layer (epitaxial layer) formed on the front surface of the support substrate “SS” is prepared. The substrate layer has: a collector region CR made of a p-type semiconductor region formed on the front surface of the support substrate SS; a buffer layer BUF made of an n-type semiconductor layer formed on the corrector region CR; and a drift layer DRL made of an n-type semiconductor layer formed on the buffer layer BUF.

This drift layer DRL has an n⁻-first drift region DRL1 formed on the support substrate SS and an n⁻-second drift region DRL2 formed on the n⁻-first drift region. Moreover, there is a relation of “nDB>nD1>nD2” among the concentration (nDB) of the n-type impurity in the buffer layer BUF, the concentration (nD1) of the n-type impurity in the n⁻-first drift region DRL1 and the concentration (nD2) of the n-type impurity in the n⁻-second drift region DRL2. Moreover, there is a relation of “LD1<LD2” between the film thickness (LD1) of the n⁻-first drift region DRL1 and the film thickness (LD2) of the n⁻-second drift region DRL2. Such a substrate “S” is prepared. A method of manufacturing this substrate “S” will be explained in a third embodiment to be described later.

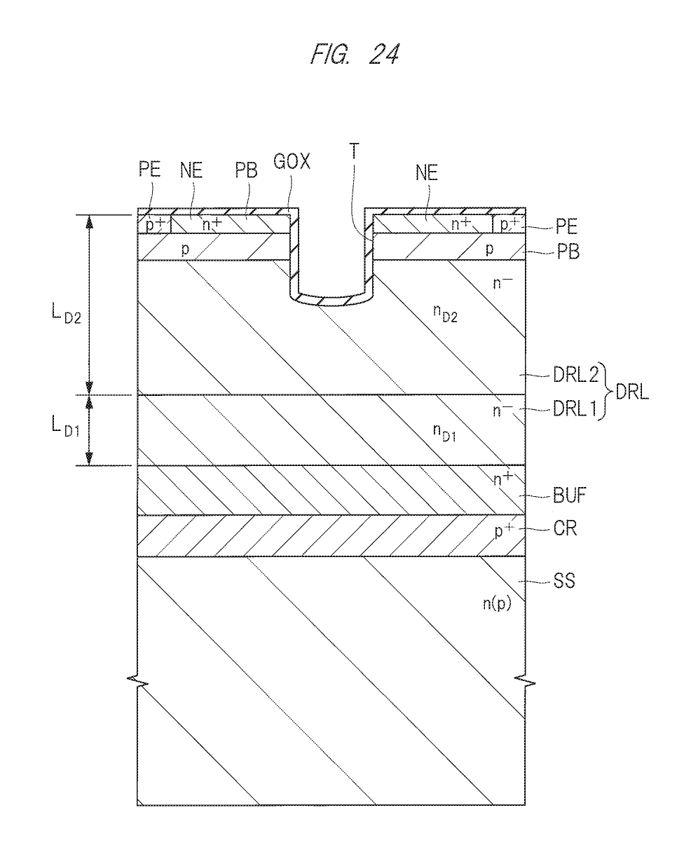

Next, as shown in FIG. 23, on the exposed surface side of the drift layer DRL (n⁻-second drift region DRL2), a P-type body region PB, an N-type emitter region NE and a P-type emitter region PE are formed. These regions can be formed by, for example, an ion implantation method as similar to the first embodiment. Note that the P-type body region PB and the N-type emitter region NE formed on both sides of the n⁻-second drift region DRL2 may be continuously formed. That is, the P-type body region PB and the N-type emitter region NE may also be formed at the center of the n⁻-second drift region DRL2.

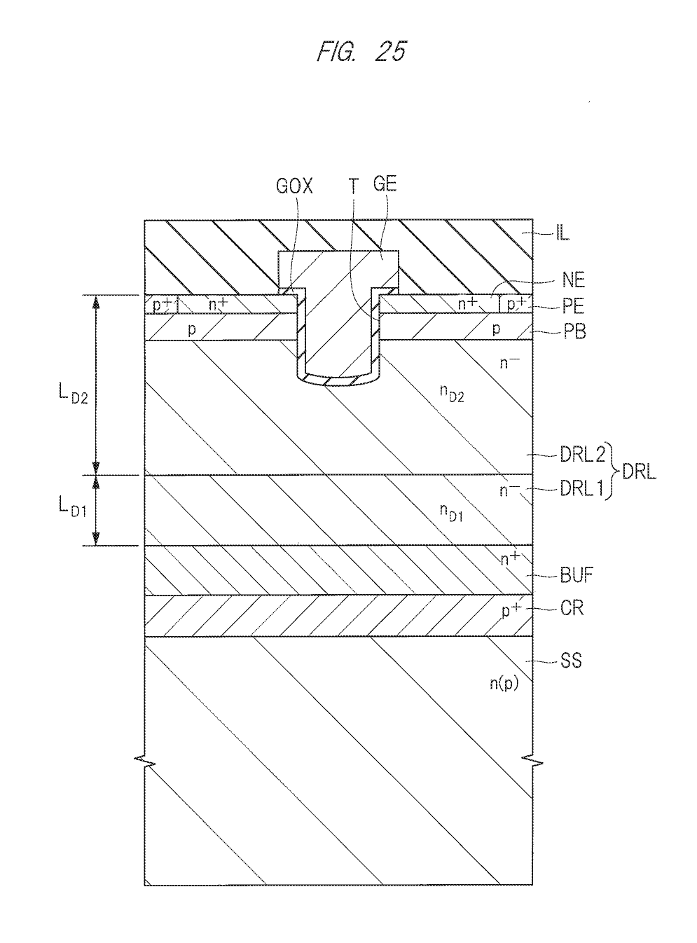

Next, as shown in FIG. 24, a trench “T” is formed in the drift layer DRL (n⁻-second drift region DRL2). For example, a mask film having an opening in the formation region of the trench is formed, and the drift layer DRL (n⁻-second drift region DRL2) is etched while using this mask film as a mask, so that the trench T is formed. Next, the mask film is removed, and a gate insulating film GOX is formed on the inner surface of the trench T, the N-type emitter region NE and the P-type emitter region PE. The gate insulating film GOX can be formed as similar to the case of the first embodiment.

Next, as shown in FIG. 25, a gate electrode GE is formed on the gate insulating film GOX. For example, on the gate insulating film GOX, a polysilicon film having such a film thickness as to be buried is formed by the CVD method. Note that an amorphous silicon film may be formed first, and then, this film may be transformed into a polysilicon film by a subsequent heating treatment. Next, by patterning the polysilicon film as similar to the case of the first embodiment, the gate electrode GE is formed. Next, as similar to the case of the first embodiment, an interlayer insulating film IL is formed on the gate electrode GE, the N-type emitter region NE and the P-type emitter region PE.

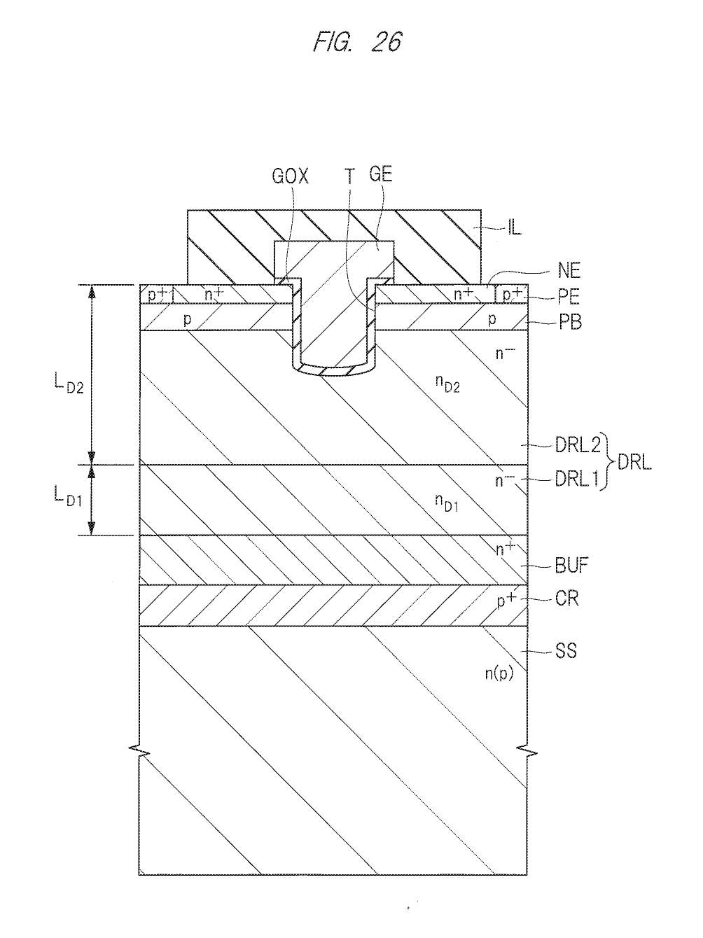

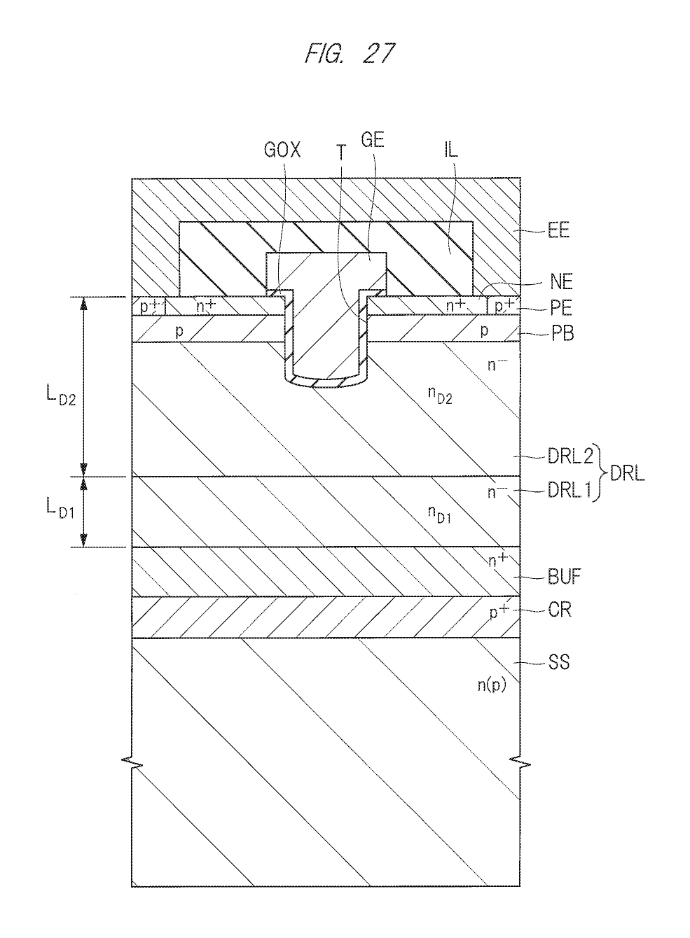

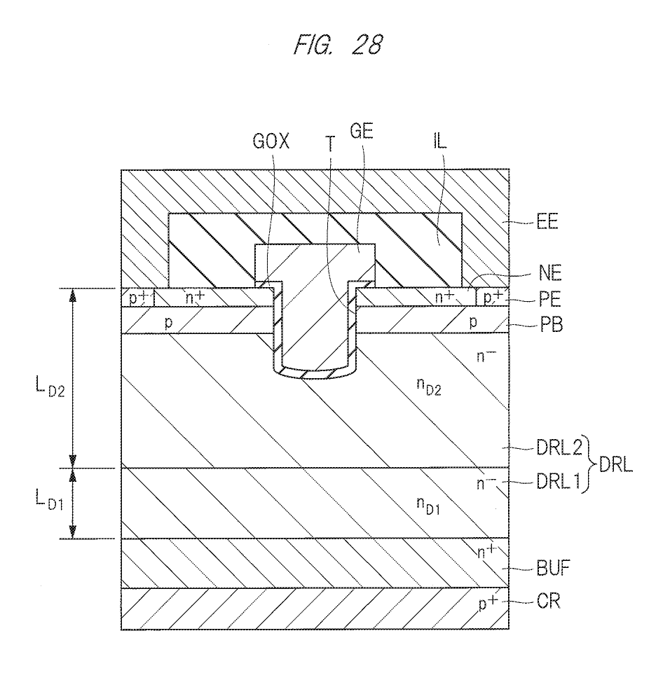

Next, as shown in FIG. 26, as similar to the case of the first embodiment, the interlayer insulating film IL on the N-type emitter region NE and the P-type emitter region PE is etched, and an emitter electrode EE is formed on the exposed regions of the N-type emitter region NE and the P-type emitter region PE as well as on the interlayer insulating film IL (FIG. 27).

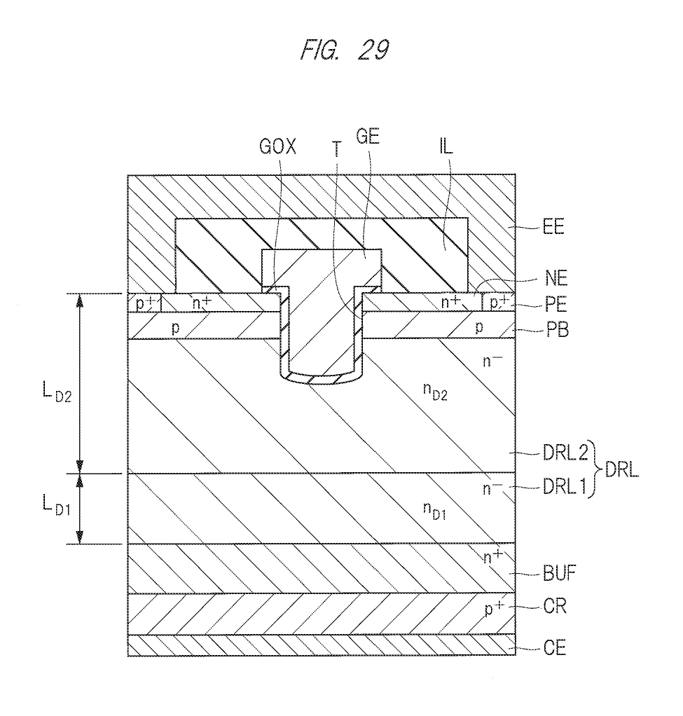

Next, as shown in FIG. 28, as similar to the case of the first embodiment, the support substrate SS is removed by polishing the support substrate SS of the substrate S while taking the rear surface side of the support substrate SS as the upper side, and a collector electrode CE is formed on the exposed surface (lower surface) of the collector region CR (FIG. 29).

### Applied Example

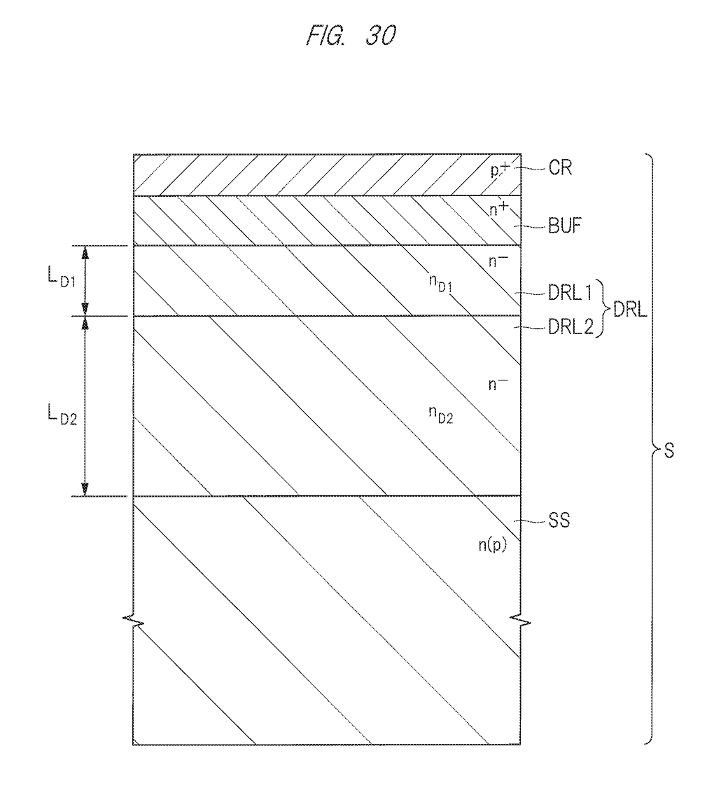

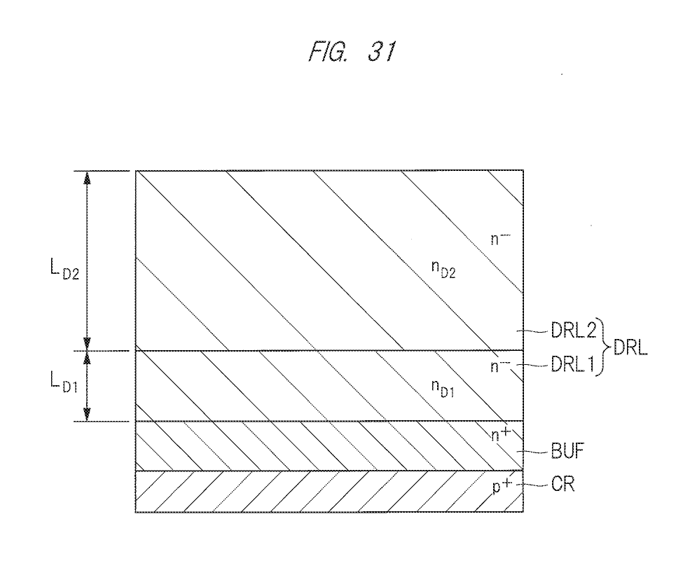

In the above-described manufacturing processes, for example, the substrate S as shown in FIG. 22 is used, the substrate being formed by sequentially stacking the collector region CR, the buffer layer BUF and the drift layer DRL on the support substrate SS. However, a substrate having another structure may be also used. Each of FIG. 30 to FIG. 32 is a cross-sectional view showing manufacturing processes of a semiconductor device according to an applied example of the present embodiment.

For example, as shown in FIG. 30, the substrate S containing SiC as a main material has a support substrate (base substrate part) SS made of an n-type or p-type semiconductor layer, a drift layer DRL made of an n-type semiconductor layer formed on the front surface of the support substrate SS, a buffer layer BUF made of an n-type semiconductor layer formed on the drift layer DRL and a collector region CR made of a p-type semiconductor region formed on the buffer layer BUF.

This drift layer DRL has an n⁻-first drift region DRL1 formed on the support substrate SS and an n⁻-second drift region DRL2 formed on the n⁻-first drift region. Moreover, there is a relation of “nDB>nD1>nD2” among the concentration (nDB) of the n-type impurity in the buffer layer BUF, the concentration (nD1) of the n-type impurity in the n⁻-first drift region DRL1 and the concentration (nD2) of the n-type impurity in the n⁻-second drift region DRL2.

Moreover, there is a relation of “LD1<LD2” between the film thickness (LD1) of the n⁻-first drift region DRL1 and the film thickness (LD2) of the n⁻-second drift region DRL2 . Such a substrate “S” is prepared. A method of manufacturing this substrate “S” will be explained in a third embodiment to be described later.

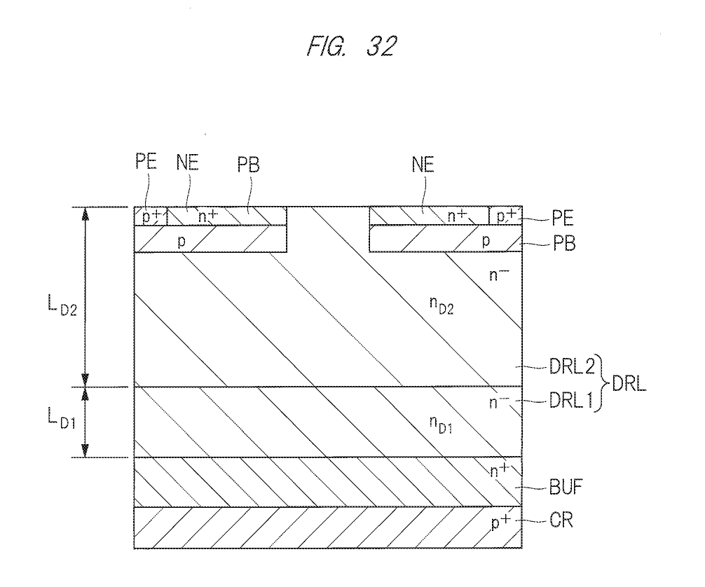

Next, the support substrate SS is removed by polishing the support substrate SS of the substrate S while taking the rear surface side of the support substrate SS as the upper side. Thus, the upper surface of the drift layer DRL (n⁻-second drift region DRL2) is exposed (FIG. 31).

Next, as shown in FIG. 32, a P-type body region PB, an N-type emitter region NE and a P-type emitter region PE are formed on the exposed surface side of the drift layer DRL (n⁻-second drift region DRL2). These regions can be formed by, for example, the ion implantation method as similar to the above-described manufacturing processes. After this, a gate insulating film GOX, agate electrode GE, an interlayer insulating film IL and an emitter electrode EE are sequentially formed on the drift layer DRL or others as similar to the above-described manufacturing processes, and besides, a collector electrode CE is formed below the collector region CR.

### Third Embodiment

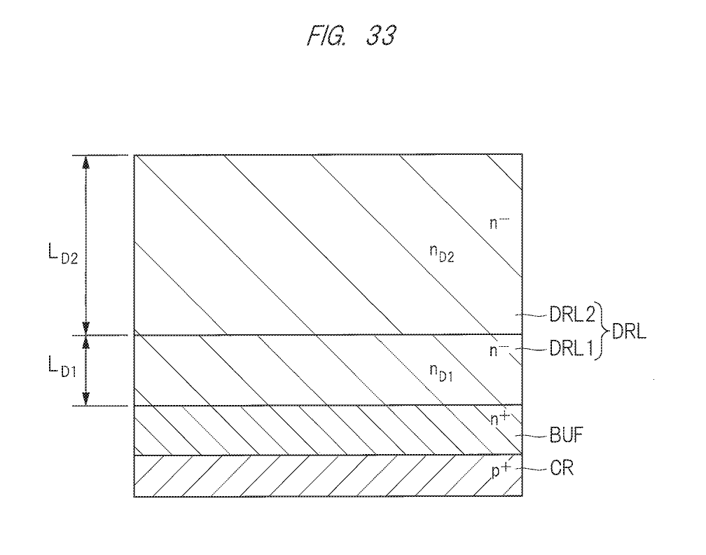

In the present embodiment, the substrate (substrate layer) used for the semiconductor device explained in the first and second embodiments will be explained. FIG. 33 is a cross-sectional view showing the substrate layer used for the semiconductor device of the present embodiment.

The semiconductor device explained in the first and second embodiments is formed by using the substrate layer. As shown in FIG. 33, this substrate layer has a collector region CR, a buffer layer BUF formed on the collector region and a drift layer DRL formed on the buffer layer. Moreover, this substrate layer contains SiC as a main material.

In addition, this drift layer DRL has an n⁻-first drift region DRL1 and an n⁻-second drift region DRL2. The n⁻-first drift region DRL1 is formed on the buffer layer BUF, and the n⁻-second drift region DRL2 is formed on the n⁻-first drift region DRL1. The concentration (nD1) of an n-type impurity in the n⁻-first drift region DRL1 is smaller (lower) than the concentration (nDB) of an n-type impurity in the buffer layer BUF. The concentration (nD2) of an n-type impurity in the n⁻-second drift region DRL2 is smaller than the concentration (nD1) of the n-type impurity in the n⁻-first drift region DRL1. That is, these concentrations have a relation of “the concentration (nDB) of the n-type impurity in the buffer layer BUF>the concentration (nD1) of the n-type impurity in the n⁻-first drift region DRL1>the concentration (nD2) of the n-type impurity in the n⁻-second drift region DRL2”. Moreover, the film thickness (LD2) of the n⁻-second drift region DRL2 is larger (thicker) than the film thickness (LD1) of the n⁻-first drift region DRL1. That is, the film thicknesses have a relation of “the film thickness (LD2) of the n⁻-second drift region DRL2>the film thickness (LD1) of the n⁻-first drift region DRL1”.

By previously preparing such a substrate layer, the semiconductor device having favorable characteristics explained in the first and second embodiments can be easily formed.

The substrate layer shown in FIG. 33 is formed on, for example, the support substrate SS as explained in the manufacturing processes of the first and second embodiments. That is, the substrate to be used for manufacturing the semiconductor device of the present embodiment has the support substrate SS and the substrate layer shown in FIG. 33.

Specifically, a configuration example and a manufacturing method example of the substrate used for manufacturing the semiconductor device of the present embodiment will be explained below.

### First Configuration Example

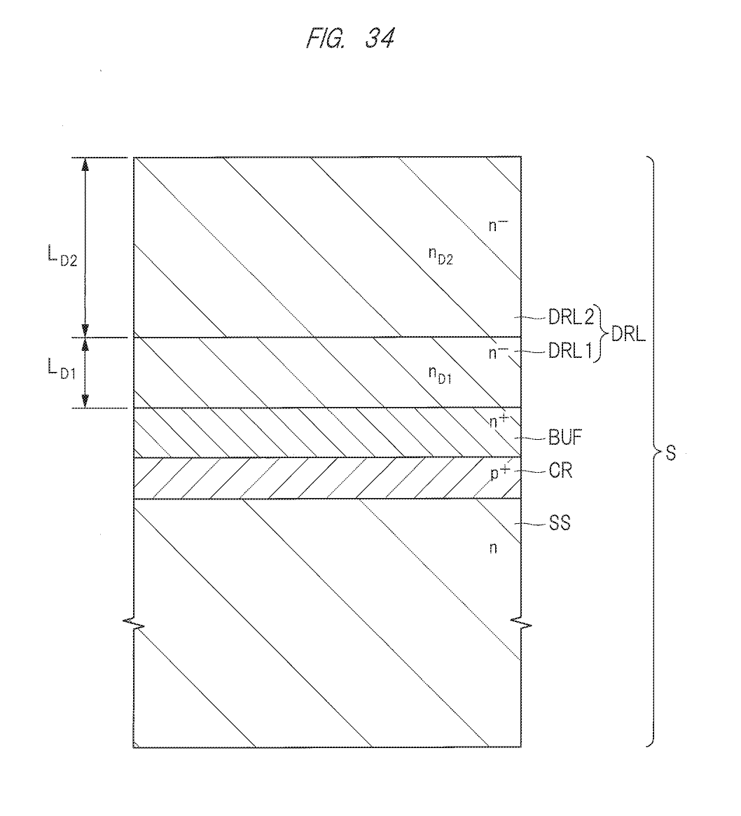

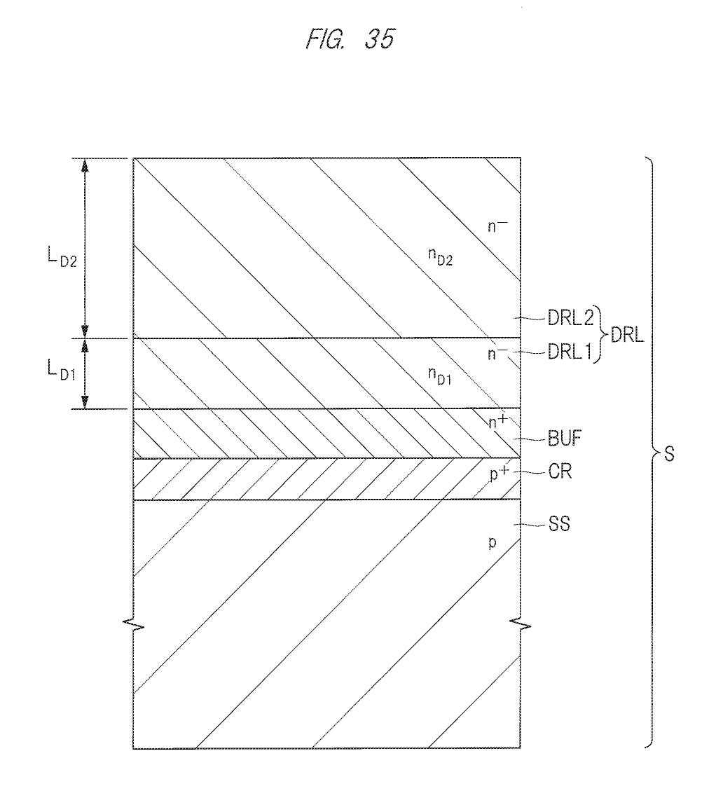

FIG. 34 is a cross-sectional view showing a first configuration example of a substrate used for manufacturing a semiconductor device of the present embodiment. At this stage, note that the substrate is, for example, a thin semiconductor plate whose plane has a substantially round shape and which is referred to as “wafer”.

As shown in FIG. 34, a substrate “S” of the present configuration example has a substrate layer (collector region CR, buffer layer BUF, drift layer DRL) formed on a support substrate SS. As the support substrate SS, for example, an n-type bulk substrate (for example, SiC substrate) can be used. By allowing SiC to be epitaxially grown on the n-type bulk substrate while introducing a p-type impurity thereto, a collector region CR that is a p⁺-type semiconductor region can be formed. Next, by allowing SiC to be epitaxially grown on the collector region CR while introducing an n-type impurity thereto, a buffer layer BUF serving as an n⁺-type semiconductor region can be formed. Next, by allowing SiC to be epitaxially grown on the buffer layer BUF while introducing an n-type impurity thereto, an n⁻-first drift region DRL1 can be formed. Moreover, by allowing SiC to be epitaxially grown on the n⁻-first drift region DRL1 while introducing an n-type impurity thereto, an n⁻-second drift region DRL2 can be formed.

In the above-described epitaxial growth, these concentrations of the n-type impurities are adjusted so as to have a relation of “the concentration (nDB) of the n-type impurity in the buffer layer BUF>the concentration (nD1) of the n-type impurity in the n⁻-first drift region DRL1>the concentration (nD2) of the n-type impurity in the n⁻-second drift region DRL2”. Moreover, in the above-described epitaxial growth, the thicknesses are adjusted so that the film thickness (LD2) of the n⁻-second drift region DRL2 is larger (thicker) than the film thickness (LD1) of the n⁻-first drift region DRL1.

In this manner, the substrate “S” of the present configuration example can be formed. After this, in accordance with the processes explained in the sections of “Explanation of Manufacturing Method” in the first and second embodiments, the semiconductor devices explained in the first and second embodiments can be formed.

Note that the n-type bulk substrate is used in the above-described embodiment. However, as shown in FIG. 35, a p-type bulk substrate may be used as the support substrate SS. FIG. 35 is a cross-sectional view showing another example of the substrate used for manufacturing the semiconductor device of the present embodiment.

When a semiconductor device is manufactured by using the substrate of the present configuration example, respective constituent parts of the semiconductor device may be formed after a configuration only including the substrate layer (collector region CR, buffer layer BUF, drift layer DRL) is formed by polishing the substrate S to remove the support substrate SS. Alternatively, after the respective constituent parts of the semiconductor device is formed, the substrate S may be polished to remove the support substrate SS.

For example, the film thickness of the drift layer of the SiC-IGBT is set to about 140 μm at a breakdown voltage of 15 kV and about 60 μm at a breakdown voltage of 6.5 kV. However, when the drift layer has multiple layers, the epitaxial growth becomes unstable at an end of the wafer, and therefore, there is a risk of reduction in the strength of the end of the wafer. In such a case, by forming the respective constituent parts of the semiconductor device while the support substrate SS exists below the substrate layer, cracking (breakage) of the wafer can be reduced.

### Second Configuration Example

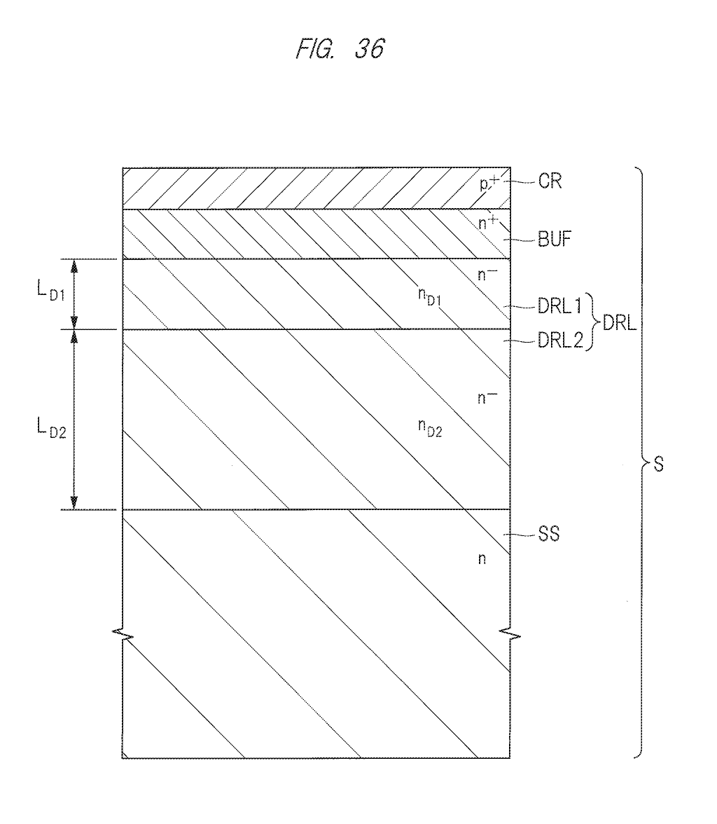

FIG. 36 is a cross-sectional view showing a second configuration example of a substrate used for manufacturing a semiconductor device of the present embodiment. At this stage, note that the substrate is, for example, a thin semiconductor plate whose plane has a substantially round shape and which is referred to as “wafer”.

As shown in FIG. 36, a substrate “S” of the present configuration example has a substrate layer (collector region CR, buffer layer BUF, drift layer DRL) formed on a support substrate SS. However, as different from the first configuration example, the support substrate SS is disposed on the drift layer DRL side of the substrate layer (collector region CR, buffer layer BUF, drift layer DRL). That is, on the support substrate SS, the n⁻-second drift region DRL2, the n⁻-first drift region DRL1, the buffer layer BUF and the collector region CR are sequentially stacked.

As the support substrate SS, for example, an n-type bulk substrate (for example, SiC substrate) can be used. By allowing SiC to be epitaxially grown on this n-type bulk substrate while introducing an n-type impurity thereto, the n⁻-second drift region DRL2 can be formed. Next, by allowing SiC to be epitaxially grown on the n⁻-second drift region DRL2 while introducing an n-type impurity thereto, the n⁻-first drift region DRL1 can be formed. Next, by allowing SiC to be epitaxially grown on the n⁻-first drift region DRL1 while introducing an n-type impurity thereto, the buffer layer BUF can be formed. Moreover, by allowing SiC to be epitaxially grown on the buffer layer BUF while introducing a p-type impurity thereto, the collector region CR that is a p⁺-type semiconductor region can be formed.

In the above-described epitaxial growth, these concentrations of the n-type impurities are adjusted so as to have a relation of “the concentration (nDB) of the n-type impurity in the buffer layer BUF>the concentration (nD1) of the n-type impurity in the n⁻-first drift region DRL1>the concentration (nD2) of the n-type impurity in the n⁻-second drift region DRL2”. Moreover, in the above-described epitaxial growth, the thicknesses are adjusted so that the film thickness (LD2) of the n⁻-second drift region DRL2 is larger (thicker) than the film thickness (LD1) of the n⁻-first drift region DRL1.

In this manner, the substrate “S” of the present configuration example can be formed. After this, in accordance with the processes explained in the sections of “Explanation of Manufacturing Method” in the first and second embodiments, the semiconductor devices explained in the first and second embodiments can be formed.

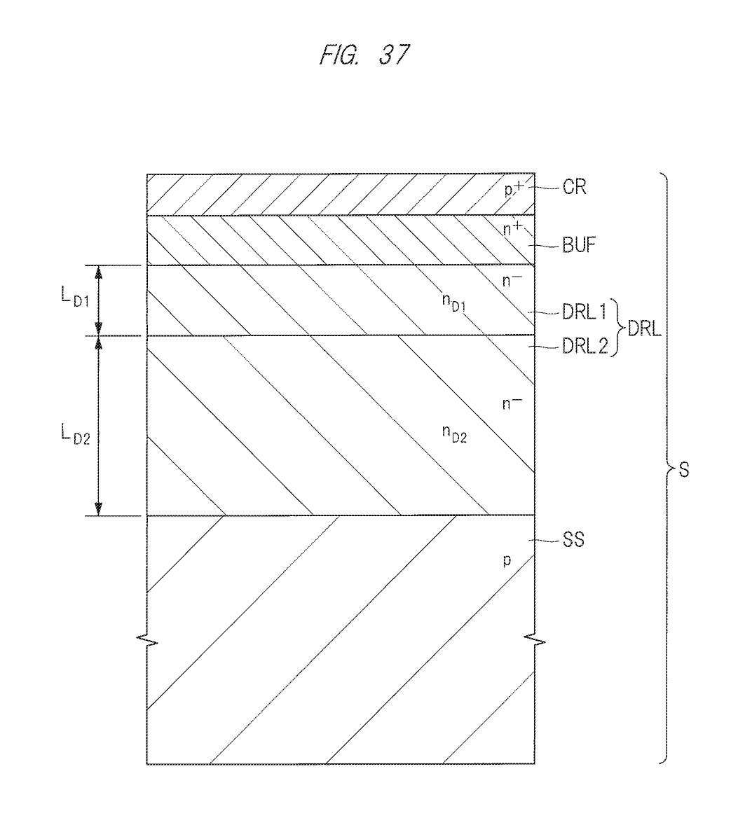

Note that the n-type bulk substrate is used in the above-described embodiment. However, as shown in FIG. 37, a p-type bulk substrate may be used as the support substrate SS. FIG. 37 is a cross-sectional view showing another example of the substrate used for manufacturing the semiconductor device of the present embodiment.

When a semiconductor device is manufactured by using the substrate of the present configuration example, respective constituent parts of the semiconductor device are formed so as to take the n⁻-second drift region DRL2 side as an upper side after a configuration only including the substrate layer (collector region CR, buffer layer BUF, drift layer DRL) is formed by polishing the substrate S to remove the support substrate SS.

When the concentration of the drift layer is increased as described above, there is a possibility of weakening the minority carrier storage effect depending on a design, which results in a large conduction loss. However, since the SiC epitaxial layer generally grows on the Si plane, the channel part below the gate insulating film on the emitter region side is oriented to the “C” plane. The resistance of such a channel part oriented to the C plane becomes higher than that of the Si plane. Thus, the injection efficiency of the electrons from the emitter region side becomes higher, so that the carrier storage effect can be enhanced. Consequently, the degree of freedom in the design can be expanded.

In the present embodiment, note that the respective layers (collector region CR, buffer layer BUF, drift layer DRL) of the substrate layer are formed by the epitaxial growth that is performed while introducing the impurity. However, the impurity may be introduced by using an ion implantation method or others. For example, after the epitaxial growth of SiC, the impurity is introduced to the SiC layers by the ion implantation method or others.

### Fourth Embodiment

Although a location to which the semiconductor device (SiC-IGBT) explained in the first and second embodiments is applied is not limited, the above-described semiconductor device can be applied to, for example, an electrical power conversion device.

Here, the electrical power conversion device for use in a railway vehicle will be explained as an example.

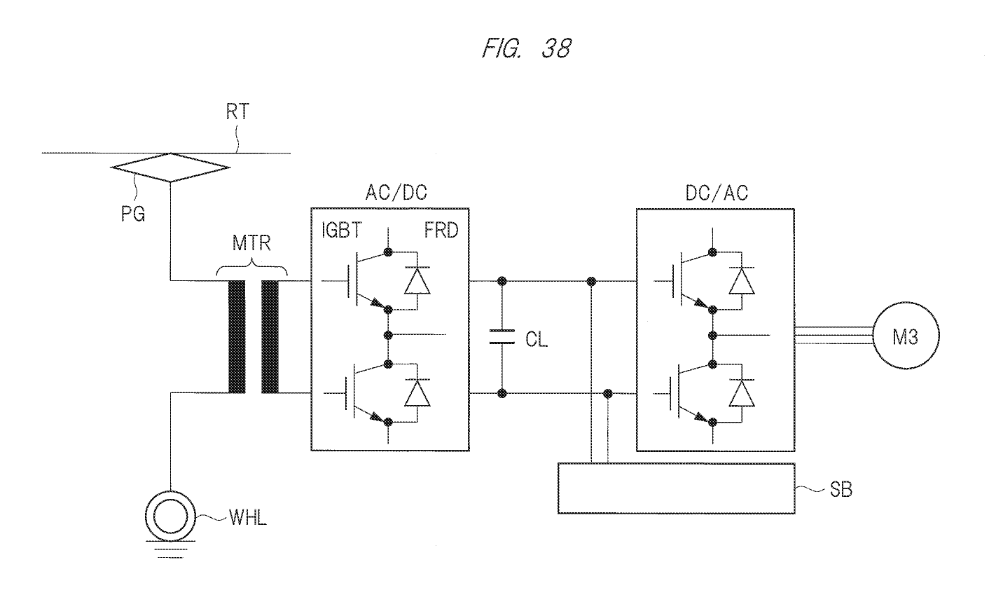

FIG. 38 is a schematic diagram showing a configuration of a railway vehicle according to the present embodiment. As shown in FIG. 38, the railway vehicle includes a pantograph PG serving as a power collector, a transformer MTR, an electrical power conversion device DC/AC, a three-phase motor M3 serving as an alternate-current electric motor, and wheels WHL. The electrical power conversion device has a converter device AC/AD, a capacitance CL such as a capacitor, and an inverter device DC/AC.

The converter device AC/AD has an IGBT as a switching element. The switching element IGBT is disposed on each of an upper arm side that is a high voltage side and a lower arm side that is a low voltage side. The inverter device DC/AC has an IGBT as a switching element. The switching element IGBT is disposed on each of an upper arm side that is a high voltage side and a lower arm side that is a low voltage side. Note that FIG. 38 shows only one phase of three phases that are U-phase, V-phase and W-phase in the IGBT serving as the switching element.

One end of the transformer MTR on a primary side is connected to a catenary RT through the pantograph PG. The other end of the same on the primary side is connected to a railway track through the wheel WHL. One end of the transformer MTR on a secondary side is connected to a terminal of the converter device AC/AD on the upper arm side. The other end of the same on the secondary side is connected to a terminal of the converter device AC/AD on the lower arm side.

The terminal of the converter device AC/AD on the upper arm side is connected to a terminal of the inverter device DC/AC on the upper arm side. Moreover, the terminal of the converter device AC/AD on the lower arm side is connected to a terminal of the inverter device DC/AC on the lower arm side. Furthermore, a capacitor CL is connected between the terminal of the inverter device DC/AC on the upper arm side and the terminal of the inverter device DC/AC on the lower arm side. In FIG. 38, three terminals of the inverter device DC/AC on the output side are connected to the three-phase motor M3 as the U-phase, V-phase and W-phase terminals, respectively.

A high alternate-current voltage (for example, 25 kV or 15 kV) propagating from the catenary RT through the pantograph PG is transformed (dropped) to, for example, an alternate-current voltage of 3.3 kV by the transformer MTR, and then, is converted to a desired direct-current power (for example, 3.3 kV) by the converter device AC/AD. A voltage of the direct-current power that has been converted by the converter device AC/AD is smoothed by the capacitor CL. A direct-current power whose voltage has been smoothed by the capacitor CL is converted into an alternate-current voltage by the inverter device DC/AC. The alternate-current voltage that has been converted by the inverter device DC/AC is supplied to the three-phase motor M3. The three-phase motor M3 to which the alternate-current power is supplied rotates the wheels WHL, so that the railway vehicle is accelerated.

In this manner, the SiC-IGBT explained in the first and second embodiments can be applied to the converter device AC/AD and the inverter device DC/AC of the railway vehicle. When the SiC-IGBT explained in the first and second embodiments is applied, the failure frequency of the device can be lowered because the breakdown voltage characteristics of the element is high, so that a life cycle cost of a railway system can be reduced. Moreover, since higher harmonic wave noises generated at the time of switching are less, the number of components of circuits for use in removing noises can be lowered. Moreover, the device is difficult to be affected by noises from other electronic components mounted on the railway vehicle, and therefore, an adverse effect caused by the noises can be avoided.

In the foregoing, the invention made by the present inventors has been concretely described based on the embodiments. However, it is needless to say that the present invention is not limited to the foregoing embodiments and various modifications and alterations can be made within the scope of the present invention.

### EXPLANATION OF REFERENCE CHARACTERS

AC/AD converter device
BUF buffer layer
CE collector electrode
CL capacitor
CR collector region
DC/AC inverter device
DRL drift layer
DRL1 first drift region
DRL2 second drift region
EE emitter electrode
ER emitter region
GE gate electrode
GOX gate insulating film
IL interlayer insulating film
LD1 film thickness
LD2 film thickness
M3 three-phase motor
MTR transformer
nD1 concentration of n-type impurity
nD2 concentration of n-type impurity
NE N-type emitter region
PB P-type body region
PE P-type emitter region
PG pantograph
RT catenary
S substrate
SS support substrate
T trench
WHL wheel

1. A semiconductor device comprising: an insulated gate bipolar transistor,
wherein the insulated gate bipolar transistor includes:
(a) a collector region of a first conductivity type having a first surface and a second surface on a side opposite to the first surface;
(b) a buffer layer of a second conductivity type formed on the first surface of the collector region;
(c) adrift layer of the second conductivity type formed on the buffer layer;
(d) a semiconductor region of the first conductivity type formed in the drift layer;
(e) an emitter region of the second conductivity type formed in the semiconductor region;
(f) a gate insulating film formed so as to be made in contact along with the drift layer, the semiconductor region and the emitter region;
(g) a gate electrode formed on the gate insulating film; and
(h) a collector electrode formed on the second surface of the collector region, and
the drift layer includes:
(c1) a first drift region of the second conductivity type formed on the buffer layer; and
(c2) a second drift region of the second conductivity type formed on the first drift region,
(c3) an impurity concentration of the first drift region is lower than an impurity concentration of the buffer layer and higher than an impurity concentration of the second drift region, and
(c4) a film thickness of the first drift region is thinner than a film thickness of the second drift region.

2. The semiconductor device according to claim 1,
wherein a substrate layer is formed by the collector region, the buffer layer and the drift layer, and,
in the substrate layer, a semiconductor having a band gap larger than a band gap of silicon is contained as a main material.

3. The semiconductor device according to claim 2,
wherein the semiconductor having the band gap larger than the band gap of silicon is silicon carbide.

4. The semiconductor device according to claim 2,
wherein the first conductivity type is a p-type and the second conductivity type is an n-type .

5. The semiconductor device according to claim 1,
wherein the gate electrode is disposed through the gate insulating film inside a trench formed in the second drift region.

6. The semiconductor device according to claim 5,
wherein a substrate layer is formed by the collector region, the buffer layer and the drift layer, and,
in the substrate layer, a semiconductor having a band gap larger than a band gap of silicon is contained as a main material.

7. The semiconductor device according to claim 6,
wherein the semiconductor having the band gap larger than the band gap of silicon is silicon carbide.

8. The semiconductor device according to claim 6,
wherein the first conductivity type is a p-type and the second conductivity type is an n-type.

9. A substrate comprising: a substrate layer,
wherein the substrate layer includes:
(a) a collector region of a first conductivity type having a first surface and a second surface on a side opposite to the first surface;
(b) a buffer layer of a second conductivity type formed on the first surface of the collector region; and
(c) a drift layer of the second conductivity type formed on the buffer layer,
the drift layer includes:
(c1) a first drift region of the second conductivity type formed on the buffer layer; and
(c2) a second drift region of the second conductivity type formed on the first drift region,
(c3) an impurity concentration of the first drift region is lower than an impurity concentration of the buffer layer and higher than an impurity concentration of the second drift region,
(c4) a film thickness of the first drift region is thinner than a film thickness of the second drift region, and
the collector region, the buffer layer, the first drift region, and the second drift region are an epitaxial layer.

10. The substrate according to claim 9,
wherein, in the substrate layer, a semiconductor having a band gap larger than a band gap of silicon is contained as a main material.

11. The substrate according to claim 10,
wherein the semiconductor having the band gap larger than the band gap of silicon is silicon carbide.

12. The substrate according to claim 9,
wherein the substrate includes a support substrate and the substrate layer, and
the support substrate is formed on the collector region side of the substrate layer.

13. The substrate according to claim 9,
wherein the substrate includes a support substrate and the substrate layer, and
the support substrate is formed on the second drift region side of the substrate layer.

14. The substrate according to claim 9,
wherein an insulated gate bipolar transistor is formed on the substrate layer of the substrate,
the insulated gate bipolar transistor including:
(d) a semiconductor region of the first conductivity type formed in the drift layer;
(e) an emitter region of the second conductivity type formed in the semiconductor region;
(f) a gate insulating film formed so as to be made in contact along with the drift layer, the semiconductor region and the emitter region;
(g) a gate electrode formed on the gate insulating film; and
(h) a collector electrode formed on the second surface of the collector region.

15. An electrical power conversion device comprising the semiconductor device according to claim 1.
